(19) United States
(12) Patent Application Publication
(10) Pub. No.: US 2025/0081617 A1
(43) Pub. Date: Mar. 6, 2025

(54) DISPLAY DEVICE

(71) Applicant: Japan Display Inc., Tokyo (JP)

(72) Inventors: Hajime WATAKABE, Tokyo (JP); Masashi TSUBUKU, Tokyo (JP); Toshinari SASAKI, Tokyo (JP); Akihiro HANADA, Tokyo (JP); Takaya TAMARU, Tokyo (JP); Marina MOCHIZUKI, Tokyo (JP); Masahiro WATABE, Tokyo (JP)

(73) Assignee: Japan Display Inc., Tokyo (JP)

(21) Appl. No.: 18/817,366

(22) Filed: Aug. 28, 2024

(30) Foreign Application Priority Data
Aug. 30, 2023 (JP) 2023-140463

(51) Int. Cl. H01L 27/12; G02F 1/1368

(52) U.S. Cl. CPC H10D 86/60; H10D 86/423; H10D 86/451; G02F 1/1368; H10D 86/0229

(57) ABSTRACT

A display device having a plurality of pixels arranged in a matrix along a first direction and a second direction intersecting the first direction, each of the plurality of pixels includes, a transistor including an oxide semiconductor layer, a gate wiring extending in the first direction opposite the oxide semiconductor layer, and a gate insulating layer between the oxide semiconductor layer and the gate wiring, a first conductive layer provided on at least one first insulating layer above the transistor and in contact with the oxide semiconductor layer, a second insulating layer provided on the first conductive layer, a first inorganic layer provided on the second insulating layer and having openings therein, and a second inorganic layer provided on the first inorganic layer and in contact with the second insulating layer in the opening.

### CROSS-REFERENCE TO RELATED APPLICATIONS

This application claims the benefit of priority to Japanese Patent Application No. 2023-140463, filed on Aug. 30, 2023, the entire contents of which are incorporated herein by reference.

### FIELD

An embodiment of the present invention relates to a display device. Specifically, an embodiment of the present invention relates to a display device using a transistor containing an oxide semiconductor. In addition, an embodiment of the present invention relates to a method for manufacturing a display device.

### BACKGROUND

In recent years, a transistor in which an oxide semiconductor instead of amorphous silicon, low-temperature polysilicon, and single-crystal silicon is used for a channel has been developed (for example, see Japanese laid-open patent publication No. 2014-146819 and Japanese laid-open patent publication No. 2015-159315). The transistor in which an oxide semiconductor is used for a channel is simply structured and formed by low-temperature processing similar to a transistor in which amorphous silicon is used for a channel. The transistor in which an oxide semiconductor is used for a channel is known to have higher mobility and a very low off-state current than the transistor in which amorphous silicon is used for a channel.

### SUMMARY

A display device according to an embodiment of the present invention having a plurality of pixels arranged in a matrix along a first direction and a second direction intersecting the first direction, each of the plurality of pixels includes a transistor including an oxide semiconductor layer, a gate wiring extending in the first direction opposite the oxide semiconductor layer, and a gate insulating layer between the oxide semiconductor layer and the gate wiring, a first conductive layer provided on at least one first insulating layer above the transistor and in contact with the oxide semiconductor layer, a second insulating layer provided on the first conductive layer, a first inorganic layer provided on the second insulating layer and having openings therein, and a second inorganic layer provided on the first inorganic layer and in contact with the second insulating layer in the opening, wherein a coverage of the first inorganic layer covering the first insulating layer is 85% or more of an area of the pixel.

### BRIEF DESCRIPTION OF DRAWINGS

FIG. 1 is a plan view showing an outline of a display device according to an embodiment of the present invention.

FIG. 2 is a block diagram showing a circuit diagram of a display device according to an embodiment of the present invention.

FIG. 3 is a circuit diagram showing a pixel circuit of a pixel of a display device according to an embodiment of the present invention.

FIG. 4 is a cross-sectional view showing a configuration of a display device according to an embodiment of the present invention.

FIG. 5 is a plan view showing a configuration of a display device according to an embodiment of the present invention.

FIG. 6 is a plan view showing a configuration of a display device according to an embodiment of the present invention.

FIG. 7 is a sequence diagram illustrating a method for manufacturing a display device according to an embodiment of the present invention.

FIG. 8 is a sequence diagram illustrating a method for manufacturing a display device according to an embodiment of the present invention.

FIG. 9 is a cross-sectional view illustrating a method for manufacturing a display device according to an embodiment of the present invention.

FIG. 10 is a cross-sectional view illustrating a method for manufacturing a display device according to an embodiment of the present invention.

FIG. 11 is a cross-sectional view illustrating a method for manufacturing a display device according to an embodiment of the present invention.

FIG. 12 is a cross-sectional view illustrating a method for manufacturing a display device according to an embodiment of the present invention.

FIG. 13 is a cross-sectional view illustrating a method for manufacturing a display device according to an embodiment of the present invention.

FIG. 14 is a cross-sectional view illustrating a method for manufacturing a display device according to an embodiment of the present invention.

FIG. 15 is a cross-sectional view illustrating a method for manufacturing a display device according to an embodiment of the present invention.

FIG. 16 is a cross-sectional view illustrating a method for manufacturing a display device according to an embodiment of the present invention.

FIG. 17 is a cross-sectional view illustrating a method for manufacturing a display device according to an embodiment of the present invention.

FIG. 18 is a cross-sectional view illustrating a method for manufacturing a display device according to an embodiment of the present invention.

FIG. 19 is a cross-sectional view showing a configuration of a display device according to another embodiment of the present invention.

FIG. 20 is a cross-sectional view showing a configuration of a display device according to another embodiment of the present invention.

FIG. 21 is a cross-sectional view showing a configuration of a display device according to another embodiment of the present invention.

FIG. 22 is a cross-sectional view showing a configuration of a display device according to another embodiment of the present invention.

### DESCRIPTION OF EMBODIMENTS

It is known that a transistor including an oxide semiconductor has a variable property when moisture enters the oxide semiconductor. Furthermore, in a display device, a planarization film made of an organic resin layer is arranged in order to reduce unevenness formed by the transistor. Since the organic resin layer contains a large amount of moisture, if hydrogen contained in the organic resin layer enters the oxide semiconductor, the properties of the transistor may fluctuate, and the reliability of the display device may deteriorate.

An object of an embodiment of the present invention is to improve the reliability in a display device using a transistor including an oxide semiconductor.

Hereinafter, embodiments of the present invention will be described with reference to the drawings. The following invention is merely an example. A configuration that can be easily conceived by a person skilled in the art by appropriately changing the configuration of the embodiment while keeping the gist of the invention is naturally included in the scope of the present invention. For clarity of explanation, the drawings may be schematically represented with respect to widths, thicknesses, shapes, and the like of respective portions as compared with actual embodiments. However, the illustrated shapes are merely examples, and do not limit the interpretation of the present invention. In the present specification and the drawings, the same reference signs are given to the same components as those described above with respect to the above-described drawings, and detailed description thereof may be omitted as appropriate.

“Display device” refers to a structure that displays an image using an electro-optical layer. For example, the term display device may refer to a display panel that includes an electro-optical layer, or may refer to a structure with other optical members (for example, a polarized member, a backlight, a touch panel, and the like) attached to a display cell. “Electro-optical layer” may include a liquid crystal layer, an electroluminescent (EL) layer, an electrochromic (EC) layer, and an electrophoretic layer, unless there is no technical contradiction. Therefore, although the embodiment to be described later will be described by exemplifying a liquid crystal display device including a liquid crystal layer as a display device, the configuration in the present embodiment can be applied to a display device including the other electro-optical layers described above.

In the embodiments of the present invention, a direction from a substrate toward an oxide semiconductor layer is referred to as upper or above. Conversely, a direction from the oxide semiconductor layer to the substrate is referred to as lower or below. In this way, for convenience of explanation, the phrase “above” or “below” is used for description, but for example, the substrate and the oxide semiconductor layer may be arranged so that the upper and lower relationship is different from the drawings. In the following explanation, for example, the expression “oxide semiconductor layer on a substrate” merely describes the upper and lower relationship between the substrate and the oxide semiconductor layer as described above, and another member may be arranged between the substrate and the oxide semiconductor layer. The terms “above” or “below” mean a stacking order in which a plurality of layers is stacked, and when expressed as a pixel electrode above a transistor, it may be a positional relationship in which the transistor does not overlap the pixel electrode in a plan view. On the other hand, when expressed as a pixel electrode vertically above a transistor, it means a positional relationship in which the transistor overlaps the pixel electrode in a plan view.

In this specification, the expressions “a includes A, B, or C,” “a includes any of A, B, and C,” “a includes one selected from a group consisting of A, B, and C,” and the like do not exclude the case where a includes a plurality of combinations of A to C unless otherwise specified. Furthermore, these expressions do not exclude the case where a includes other elements.

In addition, the following embodiments can be combined with each other as long as there is no technical contradiction.

### First Embodiment

### [1. Outline of Display Device 10]

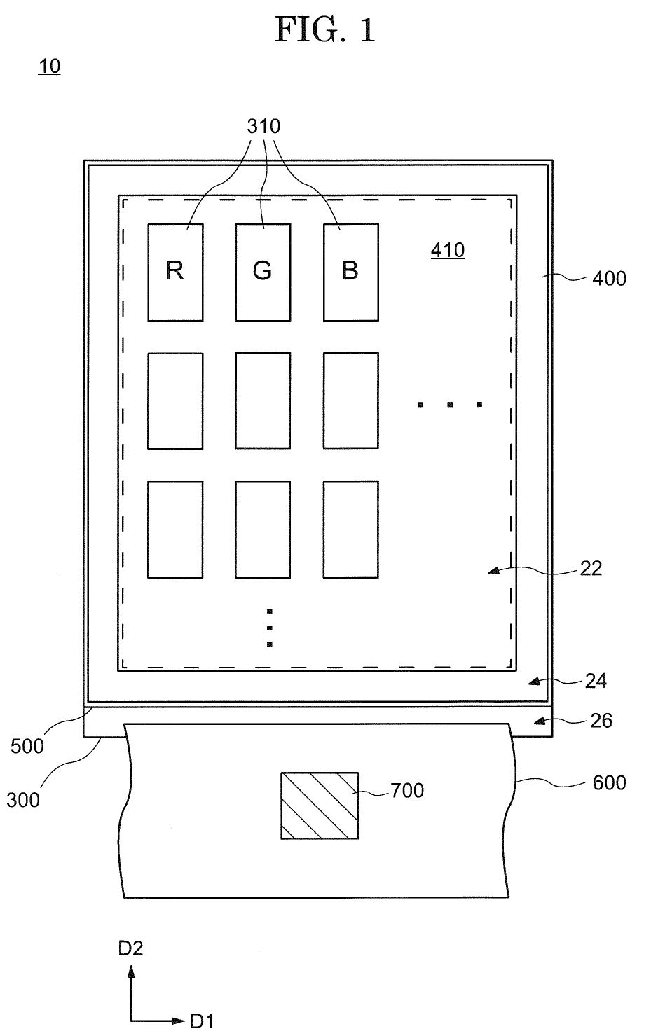

An outline of a display device 10 according to an embodiment of the present invention will be described with reference to FIG. 1 to FIG. 3. FIG. 1 is a plan view showing an outline of the display device 10 according to an embodiment of the present invention. A configuration of a liquid crystal display device as the display device 10 will be described in the present embodiment.

As shown in FIG. 1, the display device 10 includes an array substrate 300, a seal part 400, a counter substrate 500, a flexible printed circuit board 600 (FPC), and an IC chip 700. The array substrate 300 and the counter substrate 500 are bonded together by the seal part 400. In a liquid crystal region 22 surrounded by the seal part 400, a plurality of pixels 310 is arranged in a matrix along a first direction D1 (row direction) and a second direction D2 (column direction) intersecting the first direction D1. The plurality of pixels 310 includes a red pixel R, a green pixel G, and a blue pixel B according to color filters arranged in the counter substrate. Each of the red pixel R, the green pixel G, and the blue pixel B is also referred to as a sub-pixel. The first direction D1 and the second direction D2 may be perpendicular to each other. The liquid crystal region 22 is a region that overlaps a liquid crystal element 410, which will be described later, in a plan view. Hereinafter, a region of the liquid crystal region 22 including the plurality of pixels may be referred to as an image display region or an active region.

In addition, the display device 10 has a backlight unit on the back of the array substrate 300, and when outgoing light from the backlight unit passes through the image display region, the transmitted light is modulated in each pixel, so that an image is displayed.

A seal region 24 where the seal part 400 is arranged is a region around the liquid crystal region 22. The FPC 600 is arranged in a terminal region 26. The terminal region 26 is a region where the array substrate 300 is exposed from the counter substrate 500 and is arranged outside the seal region 24. In addition, the outside of the seal region 24 means the region where the seal part 400 is arranged and outside the region surrounded by the seal part 400. The IC chip 700 is arranged on the FPC 600. The IC chip 700 supplies a signal for driving a pixel circuit of each pixel 310. Hereinafter, the seal region 24 other than the image display region, the outside of the seal region 24, and the terminal region 26 may be collectively referred to as a peripheral region.

### [2. Circuit Configuration of Display Device 10]

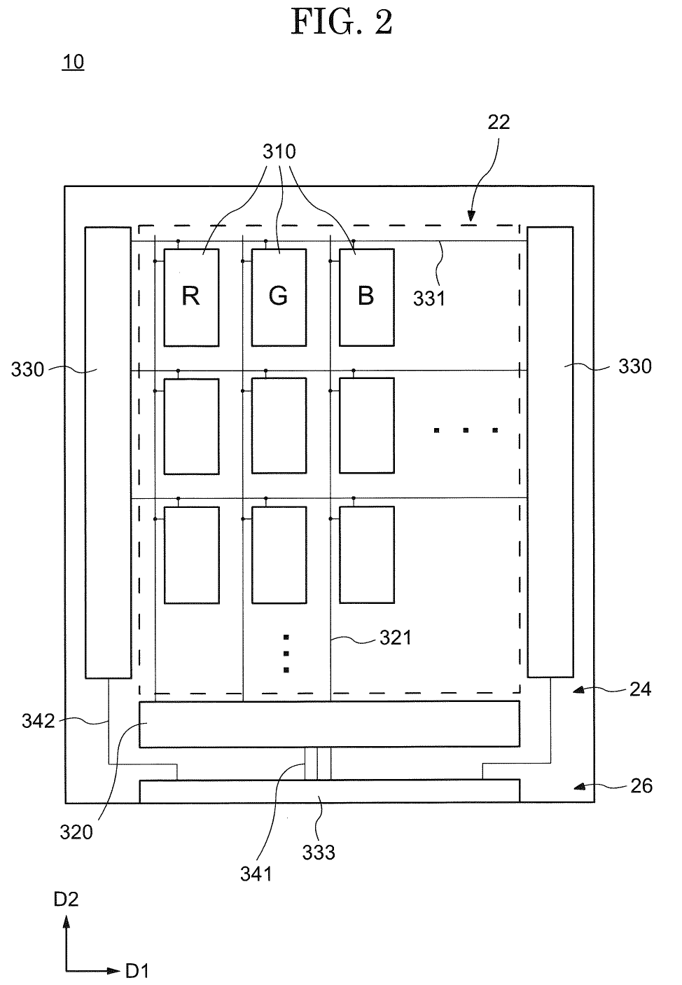

FIG. 2 is a block diagram showing a circuit configuration of the display device 10 according to an embodiment of the present invention. As shown in FIG. 2, a gate driver circuit 330 is arranged at a position adjacent to the liquid crystal region 22 where the pixel 310 is arranged in the first direction D1, and a source driver circuit 320 is arranged at a position adjacent to the liquid crystal region 22 in the second direction D2. The source driver circuit 320 and the gate driver circuit 330 are arranged in the seal region 24. However, the region where the source driver circuit 320 and the gate driver circuit 330 are arranged is not limited to the seal region 24, and any region may be used as long as it is outside the region where the pixel circuit of the pixel 310 is arranged.

A gate wiring 331 extends from the gate driver circuit 330 in the first direction D1 and is connected to the pixel circuit of the plurality of pixels 310 arranged in the first direction D1. A source wiring 321 extends from the source driver circuit 320 in the second direction D2 and is connected to the pixel circuit of the plurality of pixels 310 arranged in the second direction D2.

A terminal part 333 is arranged in the terminal region 26. The terminal part 333 and the source driver circuit 320 are connected by a connecting wiring 341. Similarly, the terminal part 333 and the gate driver circuit 330 are connected by a connecting wiring 342. When the FPC 600 is connected to the terminal part 333, an external device to which the FPC 600 is connected is connected to the display device 10, and the pixel circuit included in each pixel 310 arranged in the display device 10 is driven by a signal from the external device.

### [3. Pixel Circuit of Pixel 310 of Display Device 10]

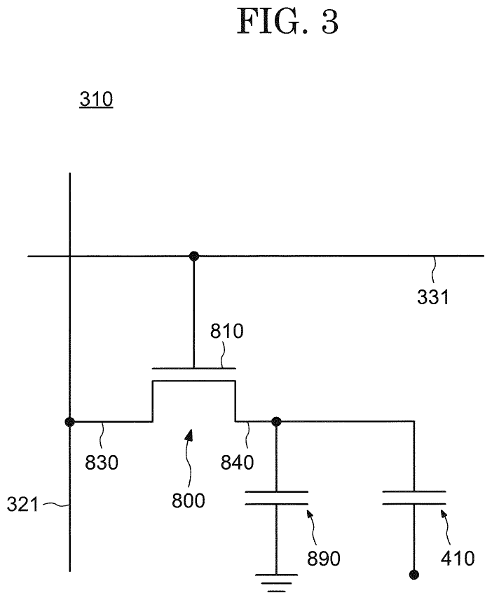

FIG. 3 is a circuit diagram showing a pixel circuit of the pixel 310 of the display device 10 according to an embodiment of the present invention. As shown in FIG. 3, the pixel circuit includes elements such as a transistor 800, a storage capacitor 890, and the liquid crystal element 410. Although details will be described later, one electrode of the storage capacitor 890 is a pixel electrode PTCO and the other electrode is a common electrode CTCO. Similarly, one electrode of the liquid crystal element 410 is the pixel electrode PTCO, and the other electrode is the common electrode CTCO. The transistor 800 includes a gate electrode 810, a source electrode 830, and a drain electrode 840. The gate electrode 810 is connected to the gate wiring 331. The source electrode 830 is connected to the source wiring 321. The drain electrode 840 is connected to the storage capacitor 890 and the liquid crystal element 410. Furthermore, for convenience of explanation, although 830 is referred to as a source electrode, and 840 is referred to as a drain electrode in the present embodiment, the function as a source and the function as a drain may be interchanged in each of the electrodes.

### [4. Configuration of Display Device 10]

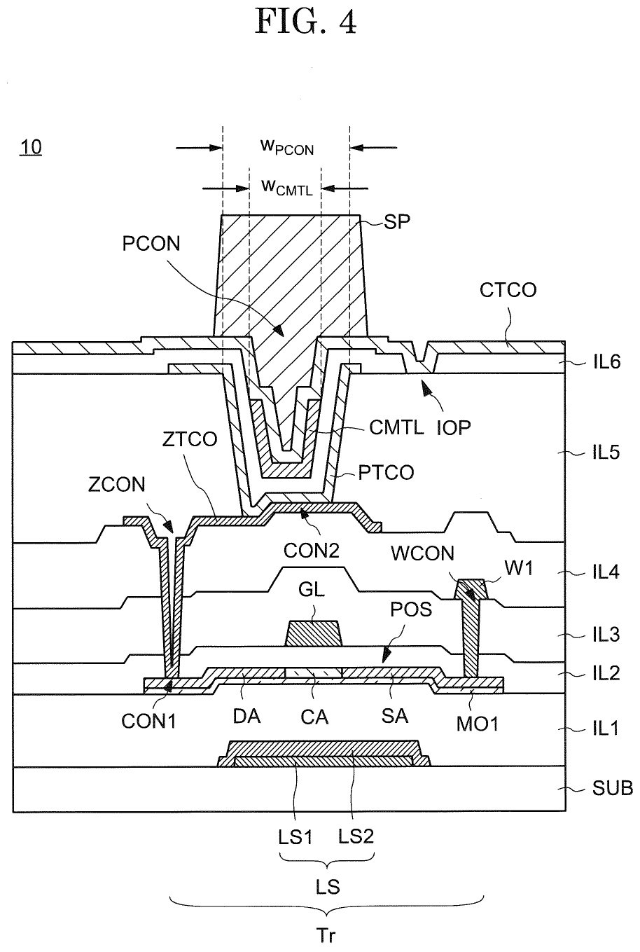

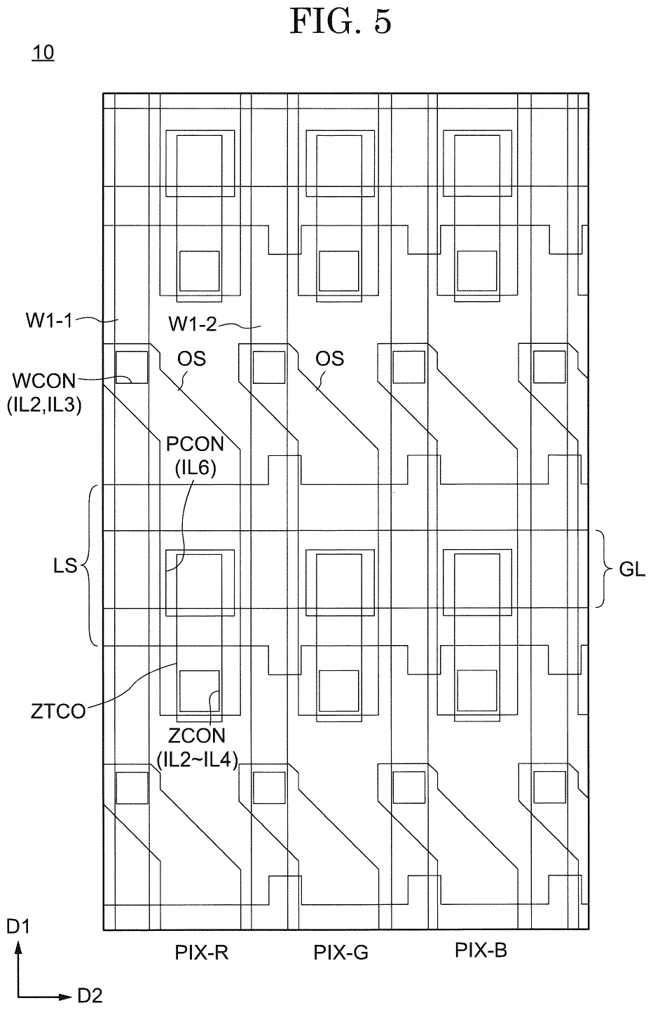

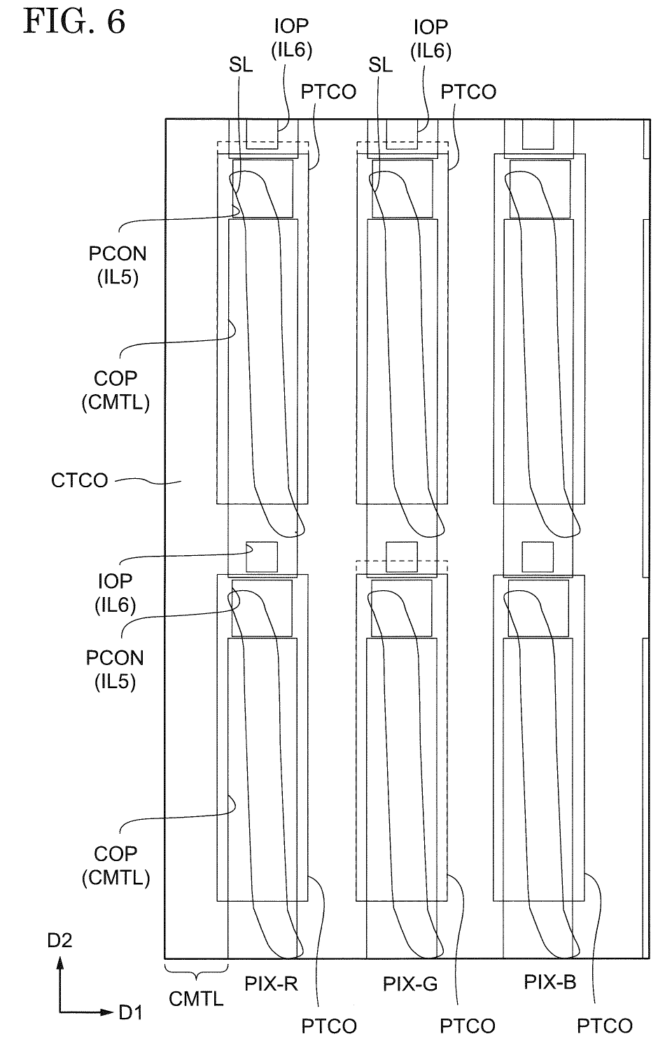

Details of the configuration of the display device 10 according to an embodiment of the present invention will be described with reference to FIG. 4 to FIG. 6. FIG. 4 is a cross-sectional view showing the configuration of the display device 10 according to an embodiment of the present invention. FIG. 5 and FIG. 6 are plan views showing the configuration of the display device 10 according to an embodiment of the present invention. In addition, the cross-sectional view in FIG. 4 is for explaining a layer structure of the display device 10, and the pixel circuit is actually arranged in the image display region. In particular, in the pixel circuit in FIG. 4, a peripheral part of a contact hole in the pixel region is mainly shown, and only part of a transmission region (opening region) that contributes to the display is shown. The liquid crystal layer and the counter substrate are not illustrated in FIG. 4. Although an FFS (Fringe Field Switching) method liquid crystal display device is shown in FIG. 4, an IPS (In Plane Switching) method liquid crystal display device may be used.

As shown in FIG. 4, the display device 10 is arranged above a substrate SUB. The display device 10 includes a transistor Tr, a wiring W1, a connecting electrode ZTCO, the pixel electrode PTCO, a common auxiliary electrode CMTL, and the common electrode CTCO. TCO is an abbreviation for Transparent Conductive Oxide. The transistor Tr is a transistor included in the pixel circuit of the pixel 310 of the display device 10.

### [5. Configuration of Transistor Tr]

The transistor Tr is arranged in a light-shielding layer LS and a first insulating layer IL1 arranged on the substrate SUB. The transistor Tr has an oxide semiconductor layer POS, a second insulating layer IL2, and a gate wiring GL (corresponding to the gate electrode 810 and the gate wiring 331 shown in FIG. 3). In addition, the transistor Tr may have a metal oxide layer MO1 arranged between the oxide semiconductor layer POS and the first insulating layer IL1. The gate wiring GL faces the oxide semiconductor layer POS. The second insulating layer IL2 is arranged between the oxide semiconductor layer POS and the gate wiring GL. Although a top-gate transistor in which the oxide semiconductor layer POS is arranged closer to the substrate SUB than the gate wiring GL is exemplified in the present embodiment, a bottom-gate transistor in which the positional relationship between the gate wiring GL and the oxide semiconductor layer POS is reversed may be used.

The oxide semiconductor layer POS has a polycrystalline structure containing a plurality of crystal grains. Although details will be described later, using a Poly-OS (Poly-crystalline Oxide Semiconductor) technique makes it possible to form the oxide semiconductor layer POS having a polycrystalline structure. Hereinafter, the oxide semiconductor having a polycrystalline structure may be referred to as a Poly-OS.

Although details will be described later, the oxide semiconductor layer POS contains two or more metals including indium, and the ratio of indium in the two or more metals is 50% or more. A gallium (Ga), a zinc (Zn), an aluminum (Al), a hafnium (Hf), an yttrium (Y), a zirconium (Zr), and a lanthanoid are used as a metal element other than the indium. However, it is sufficient that the oxide semiconductor layer POS contains the Poly-OS, and other metal elements may be contained.

The oxide semiconductor layer POS includes a channel region CA, a source region SA, and a drain region DA. The channel region CA is an oxide semiconductor layer in a region overlapping the gate wiring GL in a plan view. The channel region CA is switched between a conductive state and a non-conductive state depending on a voltage supplied to the gate wiring GL. The source region SA and the drain region DA are regions with lower resistance than the channel region. For example, the source region SA and the drain region DA are regions where the resistance is reduced by doping impurities into the oxide semiconductor layer POS.

The gate wiring GL is arranged along the first direction D1. The oxide semiconductor layer POS is arranged so as to intersect with the gate wiring GL. A region of the gate wiring GL overlapping the oxide semiconductor layer POS functions as a gate electrode.

A third insulating layer IL3 is arranged on the gate wiring GL. The wiring W1 (corresponding to the source electrode 830 and the source wiring 321 shown in FIG. 3) is arranged on the third insulating layer IL3. The wiring W1 is arranged along the second direction D2. The wiring W1 is connected to the source region SA via a contact hole WCON arranged in the second insulating layer IL2 and the third insulating layer IL3. A data signal related to a gradation of the pixel is transmitted to the wiring W1. A fourth insulating layer IL4 is arranged on the third insulating layer IL3 and the wiring W1. The connecting electrode ZTCO (corresponding to the drain electrode 840 shown in FIG. 3) is arranged on the fourth insulating layer IL4. The connecting electrode ZTCO is connected to the drain region DA via a contact hole ZCON arranged in the second insulating layer IL2 to the fourth insulating layer IL4. The connecting electrode ZTCO is in contact with the drain region DA at the bottom of the contact hole ZCON. The connecting electrode ZTCO is a transparent conductive layer.

A region where the connecting electrode ZTCO is in contact with the drain region DA is referred to as a first contact region CON1. Although details will be described later, the common electrode CTCO is in contact with the drain region DA in the first contact region CON1 not overlapping the gate wiring GL and the wiring W1 in a plan view. The first contact region CON1 is included in the display region of the pixel in a plan view.

A fifth insulating layer IL5 is arranged on the connecting electrode ZTCO. The fifth insulating layer IL5 releases a step formed by a structure arranged below the fifth insulating layer IL5. The fifth insulating layer IL5 may be referred to as a planarization film. The fifth insulating layer IL5 is made of an organic resin. The pixel electrode PTCO is arranged on the fifth insulating layer IL5. The pixel electrode PTCO is connected to the connecting electrode ZTCO via a contact hole PCON arranged in the fifth insulating layer IL5. A region where the connecting electrode ZTCO and the pixel electrode PTCO are in contact with each other is referred to as a second contact region CON2. The second contact region CON2 overlaps the gate wiring GL in a plan view. The pixel electrode PTCO is a transparent conductive layer.

A sixth insulating layer IL6 is arranged on the pixel electrode PTCO. The common auxiliary electrode CMTL and the common electrode CTCO are arranged on the sixth insulating layer IL6. Although details will be described later, the common auxiliary electrode CMTL and the common electrode CTCO have different planar patterns. The common auxiliary electrode CMTL is a metal layer. The common electrode CTCO is a transparent conductive layer. The electric resistance of the common auxiliary electrode CMTL is lower than the electric resistance of the common electrode CTCO. In addition, the common auxiliary electrode CMTL also functions as a light-shielding layer. For example, since the common auxiliary electrode CMTL blocks light from adjacent pixels, the occurrence of color mixing is suppressed. A spacer SP is arranged on the common electrode CTCO.

The common auxiliary electrode CMTL is arranged in a grid pattern in a plan view. The common auxiliary electrode CMTL is arranged so as to cross the contact hole PCON in the first direction D1, and is arranged so as to overlap the wiring W1 in the second direction D2. An opening COP is arranged in the common auxiliary electrode CMTL. The opening COP corresponds to an opening of the pixel. The common electrode CTCO is arranged on the common auxiliary electrode CMTL so as to cover the entire display region. A slit pattern is arranged in the common electrode CTCO in a region overlapping the opening COP and the pixel electrode PTCO. The slit pattern also overlaps the pixel electrode PTCO. In addition, an opening IOP is arranged in the sixth insulating layer IL6, and the opening IOP will be described later.

The spacer SP is arranged for some of the pixels. For example, the spacer SP may be arranged for any one of the red pixel R, the green pixel G, and the blue pixel B. However, the spacer SP may be arranged for all the pixels. A height of the spacer SP is half the height of the cell gap. The spacer is also arranged in the counter substrate, and the spacer of the counter substrate overlaps the spacer SP in a plan view. In addition, a configuration in which the height of the spacer SP corresponds to the cell gap may also be applied. Furthermore, as shown in FIG. 4, although the spacer protrudes toward the counter substrate while being filled in the contact hole PCON, a configuration in which the contact hole is only filled with a filler may be used.

The light-shielding layer LS is arranged between the transistor Tr and the substrate SUB. The light-shielding layers LS1 and LS2 are arranged as the light-shielding layer LS in the present embodiment. However, the light-shielding layer LS may be formed of only the light-shielding layer LS1 or only the light-shielding layer LS2. The light-shielding layer LS is arranged along the first direction D1 in a region overlapping the gate wiring GL in a plan view. In addition, the light-shielding layer LS is arranged so as to intersect the oxide semiconductor layer POS. In other words, the light-shielding layer LS is arranged in a region overlapping the channel region in a plan view. The light-shielding layer LS suppresses light incident from the substrate SUB from reaching the channel region. In the case where the conductive layer is used as the light-shielding layer LS, a voltage is applied to the light-shielding layer LS to control the channel region. In the case where a voltage is applied to the light-shielding layer LS, the light-shielding layer LS and the gate wiring GL may be connected in a peripheral region of the pixel circuit. The first contact region CON1 is arranged in a region not overlapping the light-shielding layer LS in a plan view.

It is known that the transistor including an oxide semiconductor has a variable property when moisture enters the oxide semiconductor. In addition, a planarization film made of an organic resin is arranged in the display device in order to release unevenness formed by the transistor. Since the organic resin contains a large amount of moisture, when hydrogen contained in the organic resin enters the oxide semiconductor, the properties of the transistor may fluctuate, and the reliability of the display device may deteriorate.

In the display device using the transistor including the oxide semiconductor, moisture contained in an organic resin layer arranged on the transistor needs to be sufficiently released. Even if an annealing treatment is performed while the organic resin layer is exposed during the manufacturing process, moisture is again taken in from the surface of the organic resin layer exposed in the subsequent process.

For example, in the case of the liquid crystal display device, a pixel electrode, a common electrode, an auxiliary electrode, or an inorganic layer such as an inorganic insulating layer are arranged on the organic resin layer. The inorganic layer has a function of suppressing the permeation of moisture as compared with the organic resin layer. Since the organic resin layer is exposed from the pixel electrode even if the annealing treatment is performed while the pixel electrode is formed on the organic resin layer, the properties of the transistor may fluctuate due to moisture being taken in from the outside. Similarly, since the surface of the organic resin layer is exposed from the common electrode even if the annealing treatment is performed while the common electrode is formed on the organic resin layer, the properties of the transistor may fluctuate due to moisture being taken in from the outside. As the definition of the display device improves, the area of the pixel and the area occupied by the transistor are reduced. Therefore, fluctuations in the properties of the transistor greatly affect the display quality of the display device.

Therefore, in order to suppress fluctuations in the properties of the transistor including the oxide semiconductor, it is essential to release the moisture contained in the organic resin layer to the outside, and to suppress the moisture from being taken into the organic resin layer again from the outside in the subsequent process.

A first inorganic layer is arranged on the organic resin layer, and the opening IOP is arranged in the first inorganic layer in an embodiment of the present invention. The first inorganic layer covers the organic resin layer at a coverage of 85% or more with respect to the area of the pixel. A second inorganic layer is arranged on the first inorganic layer, and the second inorganic layer is in contact with the organic resin layer at the opening. That is, the opening IOP arranged in the first inorganic layer is closed by the second inorganic layer arranged on the first inorganic layer.

Performing an annealing treatment after the opening IOP is formed in the first inorganic layer in the manufacturing process of the display device 10 releases moisture contained in the organic resin layer to the outside via the opening IOP arranged in the first inorganic layer. In this case, since the first inorganic layer covers the organic resin layer at a coverage of 85% or more with respect to the area of the pixel, the moisture is intensively released from the opening IOP. In addition, it is possible to suppress moisture from entering the organic resin layer from the outside of the first inorganic layer. Furthermore, closing the opening IOP with the second inorganic layer arranged on the first inorganic layer makes it possible to further suppress moisture from entering the organic resin layer from the outside.

In the display device 10 according to an embodiment of the present invention, moisture can be suppressed from entering the organic resin layer not only during the manufacturing process but also when the display device is used by closing the opening IOP arranged in the first inorganic layer by the second inorganic layer. Therefore, it is possible to suppress moisture contained in the organic resin layer from entering the oxide semiconductor again. As a result, it is possible to suppress fluctuation in the properties of the transistor and to improve the reliability of the display device.

In this specification and the like, the area of a sub-pixel can be calculated by the following equation.

Active region/resolution=area of sub-pixel

In addition, the area of each of the red pixel R, the green pixel G, and the blue pixel B may be different depending on the display device. In this case, the three areas of the sub-pixel may be calculated as the area of one pixel. In this case, the coverage ratio at which the first inorganic layer covers the organic resin layer may be calculated by using the three areas of the sub-pixels as the area of one pixel.

For example, in the case where the active region (mm²) is 38.4 mm×38.4 mm and the resolution is 1600 (RGB)×1600, the area per sub-pixel is 192 μm². Therefore, if the first inorganic layer covers 163.2 μm² or more of the organic resin layer in the sub-pixel, the moisture contained in the organic resin layer can be released from the opening IOP of the first inorganic layer, and the moisture can be suppressed from being taken into the organic resin layer again in the subsequent process.

Each of the first inorganic layer and the second inorganic layer is formed of a conductive layer, a transparent conductive layer, and an inorganic insulating layer. Each of the first inorganic layer and the second inorganic layer may have a single-layer structure or a stacked structure. For example, the stacked structure may be a stacked structure of the transparent conductive layer and the inorganic insulating layer or a stacked structure in which a plurality of inorganic insulating layers is stacked. A thickness of each of the first inorganic layer and the second inorganic layer is not particularly limited, but is preferably 30 nm or more, and 50 nm or more and 200 nm or less. In the case where the thickness of the first inorganic layer is less than 30 nm, the blocking effect of moisture from the outside may be weakened. In this case, the second inorganic layer thicker than the first inorganic layer may be arranged on the first inorganic layer to fill the opening IOP arranged in the first inorganic layer. In addition, the thickness of the second inorganic layer may be 200 nm or more as long as the driving of the liquid crystal element is not affected.

An area of the opening IOP arranged in the sixth insulating layer IL6 may be smaller than an area of the contact hole arranged in the fifth insulating layer IL5. In other words, the first inorganic layer covers the organic resin layer at a coverage of 85% or more, preferably 95% or more, and more preferably 98% or more with respect to the area of the pixel. In the case where the area of the opening IOP is large, moisture may be taken in from the outside via the opening IOP during the annealing treatment even if moisture is released from the organic resin layer to the outside via the opening IOP. Making the area of the opening IOP smaller than the area of the contact hole makes it possible to suppress the moisture released from the organic resin layer from being taken in again.

In the structure of the display device 10 shown in FIG. 4 to FIG. 6, the first inorganic layer is the pixel electrode PTCO and the sixth insulating layer IL6, and the second inorganic layer is the common electrode CTCO. The opening IOP is arranged in the sixth insulating layer IL6. The common electrode CTCO is in contact with the fifth insulating layer IL5 in the opening IOP. The common electrode CTCO is not connected to other conductive layers in the opening IOP arranged in the pixel. In addition, the sixth insulating layer IL6 covers the fifth insulating layer IL5 at a coverage of 85% or more with respect to the area of the pixel.

Furthermore, the opening IOP arranged in the sixth insulating layer IL6 is preferably arranged in a region overlapping the oxide semiconductor layer POS. Arranging the opening IOP in the vicinity of the oxide semiconductor layer POS makes it possible to reduce the effect of moisture contained in the organic resin layer. The opening IOP is more preferably arranged so as to overlap the region of the oxide semiconductor layer POS where the gate wiring overlaps.

As described above, in the display device according to an embodiment of the present invention, after the moisture contained in the organic resin layer arranged on the transistor is released, the moisture can be suppressed from being taken in again from the outside into the organic resin layer. Fluctuations in the properties of the transistor can be suppressed by suppressing the moisture from entering the oxide semiconductor layer into the organic resin layer. Therefore, the reliability of the display device can be improved.

### [6. Method for Manufacturing Display Device]

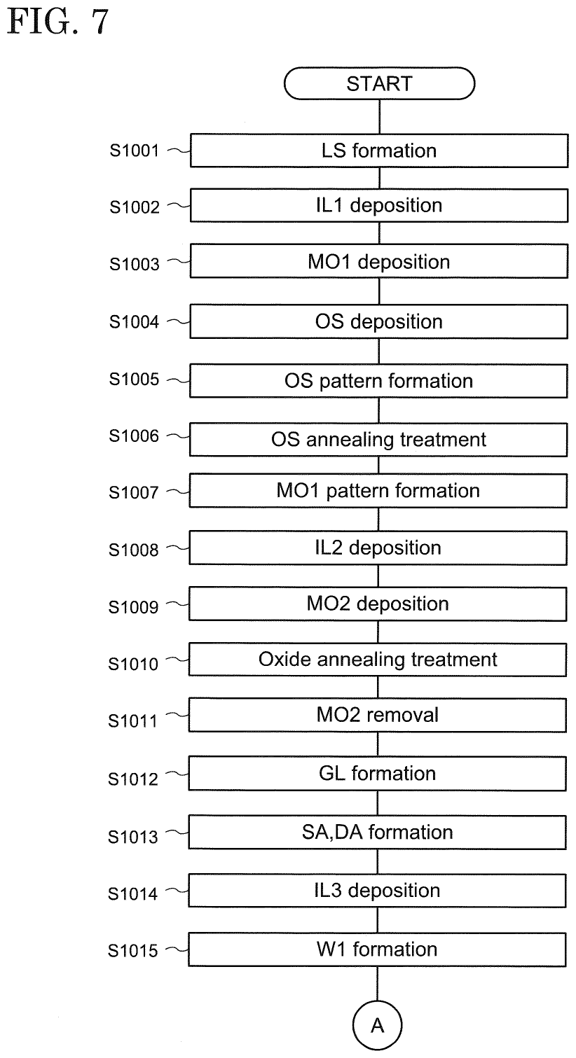

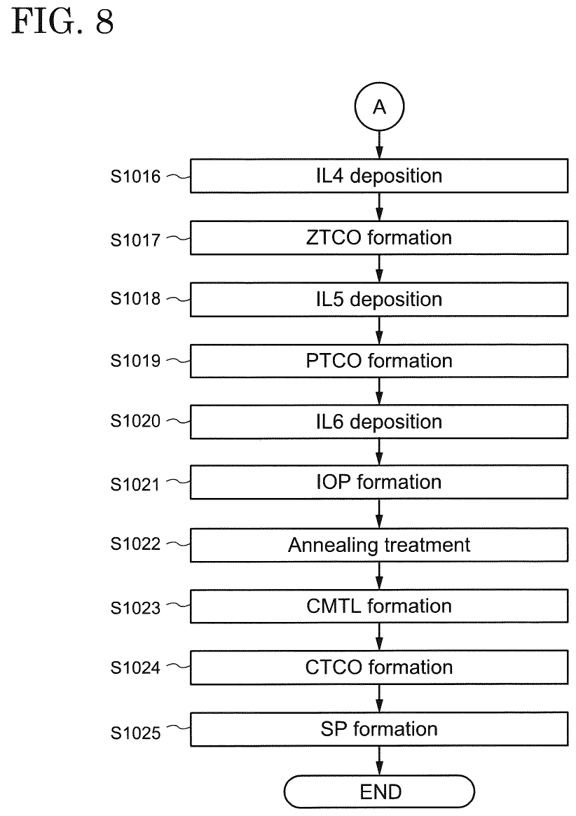

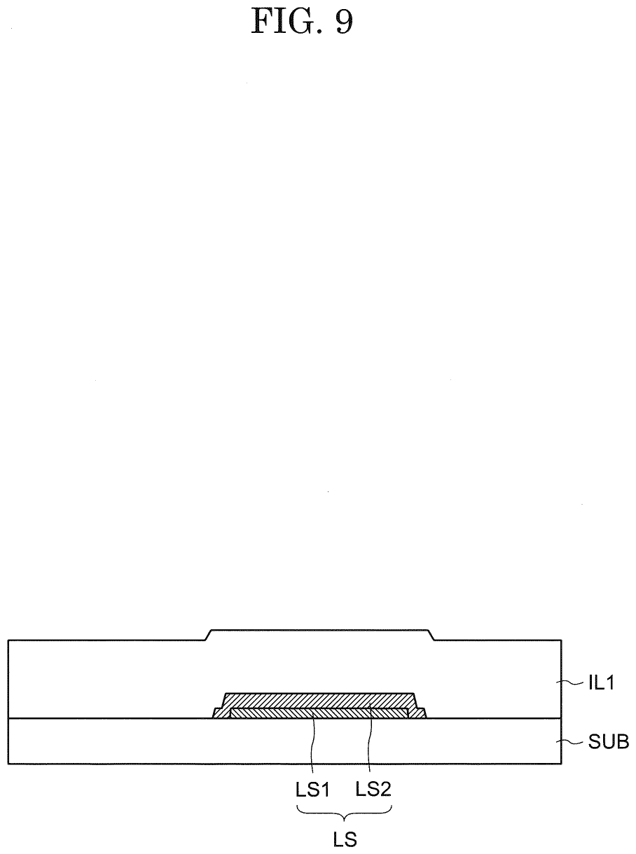

A method for manufacturing the display device 10 according to an embodiment of the present invention will be described. FIG. 7 and FIG. 8 are sequential diagrams for explaining methods for manufacturing the display device 10 according to an embodiment of the present invention. FIG. 9 to FIG. 18 are cross-sectional views illustrating the method for manufacturing the display device 10 according to an embodiment of the present invention.

First, the light-shielding layers LS1 and LS2 are formed as the light-shielding layer LS on the substrate SUB (see “LS formation” in step S1001 shown in FIG. 7 and see FIG. 9).

A rigid substrate having light transmittance, such as a glass substrate, a quartz substrate, and a sapphire substrate, is used as the substrate SUB. In the case where the substrate SUB needs flexibility, a polyimide substrate, an acrylic substrate, a siloxane substrate, a fluororesin substrate, or the like, or a substrate containing an organic resin is used as the substrate SUB. In the case where a substrate containing an organic resin is used as the substrate SUB, an impurity element may be introduced into the organic resin in order to improve the heat resistance of the substrate SUB.

For example, the light-shielding layer LS is formed by processing a conductive layer formed by a sputtering method. A common metal material is used as the light-shielding layer LS. Examples of the light-shielding layer LS include aluminum (Al), titanium (Ti), chromium (Cr), cobalt (Co), nickel (Ni), molybdenum (Mo), hafnium (Hf), tantalum (Ta), tungsten (W), bismuth (Bi), silver (Ag), copper (Cu), and an alloy or compound thereof. As shown in FIG. 9, the light-shielding layer LS1 is formed as the light-shielding layer LS, and then the light-shielding layer LS2 is formed so as to cover the light-shielding layer LS1. Although the case of stacking the light-shielding layer LS1 and the light-shielding layer LS2 will be described in the present embodiment, the light-shielding layer LS may be formed in a single layer.

Next, the first insulating layer IL1 is deposited as a base layer on the light-shielding layer LS (see “IL1 deposition” in step S1002 shown in FIG. 7 and see FIG. 9).

The first insulating layer IL1 is formed by a CVD (Chemical Vapor Deposition) method or a sputtering method. A common insulating material is used as the first insulating layer IL1. For example, an inorganic insulating material such as silicon oxide (SiOₓ), silicon oxynitride (SiOₓN_{y}), silicon nitride (SiNₓ), silicon nitride oxide (SiNₓO_{y}), aluminum oxide (AlOₓ), aluminum oxynitride (AlOₓN_{y}), aluminum nitride oxide (AlNₓO_{y}), and aluminum nitride (AlNₓ) are used as the first insulating layer IL1.

SiOₓN_{y} and AlOₓN_{y} are a silicon compound and aluminum compound containing a smaller proportion (x>y) of nitrogen (N) than oxygen (O). SiNₓO_{y} and AlNₓO_{y} are a silicon compound and aluminum compound containing a smaller proportion (x>y) of oxygen than nitrogen.

The first insulating layer IL1 is formed to have a single-layer structure or a stacked structure. In the case where the first insulating layer IL1 is a stacked structure, it is preferable that an insulating material containing nitrogen and an insulating material containing oxygen are formed in this order from the substrate SUB. For example, impurities that diffuse from the substrate SUB toward the oxide semiconductor layer POS can be blocked by using the insulating material containing nitrogen. In addition, using the insulating material containing oxygen makes it possible to release oxygen by a heat treatment. For example, the temperature of the heat treatment at which the insulating material containing oxygen releases oxygen is 600° C. or lower, 500° C. or lower, 450° C. or lower, or 400° C. or lower. That is, for example, the insulating material containing oxygen releases oxygen at a heat treatment temperature performed in a manufacturing process of the display device when the glass substrate is used as the substrate SUB. For example, silicon nitride is formed as the insulating material containing nitrogen in the present embodiment. For example, silicon oxide is formed as the insulating material containing oxygen.

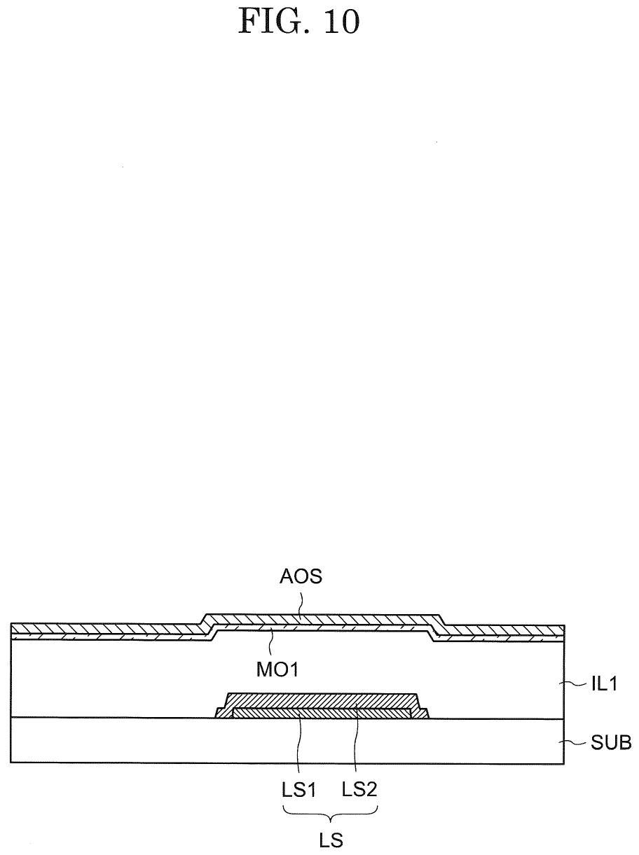

Next, the metal oxide layer MO1 containing aluminum as a main component is formed on the first insulating layer IL1 (see “MO1 deposition” in step S1003 shown in FIG. 7 and see FIG. 10).

The metal oxide layer MO1 is formed by a sputtering method. For example, an inorganic insulating layer such as aluminum oxide (AlOₓ), aluminum oxynitride (AlOₓN_{y}), aluminum nitride oxide (AlNₓO_{y}), and aluminum nitride (AlNₓ) are used as the metal oxide layer containing aluminum as a main component. The “metal oxide layer containing aluminum as a main component” means that the proportion of aluminum contained in the metal oxide layer MO1 is 1% or more of the total amount of the metal oxide layer MO1. The proportion of the aluminum contained in the metal oxide layer MO1 may be 5% or more and 70% or less, 10% or more and 60% or less, or 30% or more and 50% or less of the entire metal oxide layer MO1. The ratio may be a mass ratio or a weight ratio.

For example, the thickness of the metal oxide layer MO1 is 2 nm or more and 100 nm or less, 2 nm or more and 50 nm or less, 2 nm or more and 30 nm or less, or 2 nm or more and 15 nm or less. In the present embodiment, aluminum oxide is used as the metal oxide layer MO1. Aluminum oxide has a high barrier property against gas.

Next, an amorphous oxide semiconductor layer AOS is formed on the metal oxide layer MO1 (see “OS deposition” in step S1004 shown in FIG. 7 and see FIG. 10).

The oxide semiconductor layer AOS is deposited by a sputtering method or an atomic layer deposition method (ALD). For example, a thickness of the oxide semiconductor layer AOS is 10 nm or more and 100 nm or less, 15 nm or more and 70 nm or less, or 20 nm or more and 40 nm or less.

A metal oxide having semiconductor properties can be used as the oxide semiconductor layer AOS. For example, an oxide semiconductor containing two or more metals including indium (In) is used as the oxide semiconductor layer AOS. In addition, the proportion of indium in the two or more metals is 50% or more. Gallium (Ga), zinc (Zn), aluminum (Al), hafnium (Hf), yttrium (Y), zirconium (Zr), or lanthanoids are used as the oxide semiconductor layer AOS in addition to indium. Elements other than those described above may be used as the oxide semiconductor layer AOS. A metal oxide containing indium (In) and gallium (Ga) is used as the oxide semiconductor layer AOS in the present embodiment.

In the case where the oxide semiconductor layer is crystallized by an OS annealing treatment described later, the oxide semiconductor layer AOS after the deposition and before the OS annealing treatment is preferably amorphous (a state in which the crystalline component of the oxide semiconductor is low). That is, the deposition method of the oxide semiconductor layer AOS is preferably a condition in which the oxide semiconductor layer AOS immediately after the deposition does not crystallize as much as possible. For example, in the case where the oxide semiconductor layer AOS is formed by a sputtering method, the oxide semiconductor layer AOS is formed while controlling the temperature of an object to be film-formed (the substrate SUB and a structure formed thereon).

When deposition is performed on the object to be film-formed by the sputtering method, ions generated in a plasma and atoms recoiled by a sputtering target collide with the object to be film-formed, so that the temperature of the object to be film-formed increases with the deposition treatment. When the temperature of the object to be film-formed during the deposition treatment increases, microcrystals are contained in the oxide semiconductor layer AOS in a state immediately after the deposition, and crystallization by the subsequent OS annealing treatment is inhibited. In order to control the temperature of the object to be film-formed as described above, for example, deposition can be performed while cooling the object to be film-formed. For example, the object to be film-formed can be cooled from the surface opposite to the film-forming surface so that the temperature of the film-forming surface of the object to be film-formed (hereinafter, referred to as “deposition temperature”) is 100° C. or lower, 70° C. or lower, 50° C. or lower, or 30° C. or lower. As described above, forming the oxide semiconductor layer AOS while the object to be film-formed is cooled makes it possible to form the oxide semiconductor layer AOS with few crystalline components immediately after deposition.

Next, a pattern of the oxide semiconductor layer AOS is formed (“OS pattern formation” in step S1005 shown in FIG. 7). Although not shown, a resist mask is formed on the oxide semiconductor layer AOS, and the oxide semiconductor layer AOS is etched using the resist mask. Wet etching may be used, or dry etching may be used as the etching of the oxide semiconductor layer AOS. Wet etching can be performed using an acidic etchant. For example, oxalic acid or hydrofluoric acid can be used as the etchant.

The pattern of the oxide semiconductor layer AOS is preferably formed before the OS annealing. When the oxide semiconductor layer AOS is crystallized by the OS annealing, it tends to be difficult to etch. In addition, even if the oxide semiconductor layer AOS is damaged by the etching, the damage can be repaired by the OS annealing treatment, which is preferable.

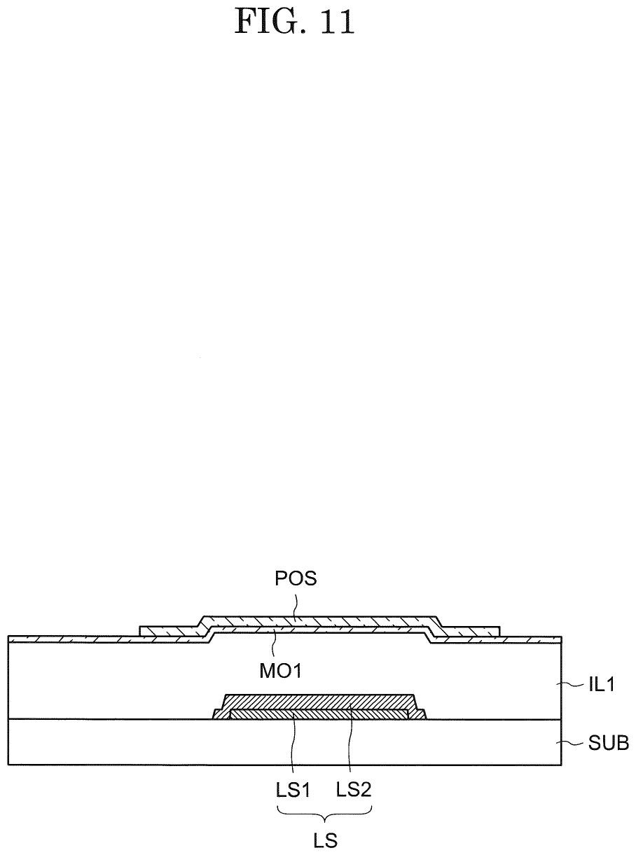

The oxide semiconductor layer AOS is subjected to a heat treatment (OS annealing treatment) after the pattern of the oxide semiconductor layer AOS is formed (see “OS annealing treatment” in step S1006 shown in FIG. 7 and see FIG. 11). In the OS annealing treatment, the oxide semiconductor layer AOS is held at a predetermined reaching temperature for a predetermined period of time. The predetermined reaching temperature is 300° C. or higher and 500° C. or lower, preferably 350° C. or higher and 450° C. or lower. In addition, the holding time at the reaching temperature is 15 minutes or more and 120 minutes or less, preferably 30 minutes or more and 60 minutes or less. The OS annealing treatment is performed, the oxide semiconductor layer AOS is crystallized, and the oxide semiconductor layer POS having a polycrystalline structure is formed.

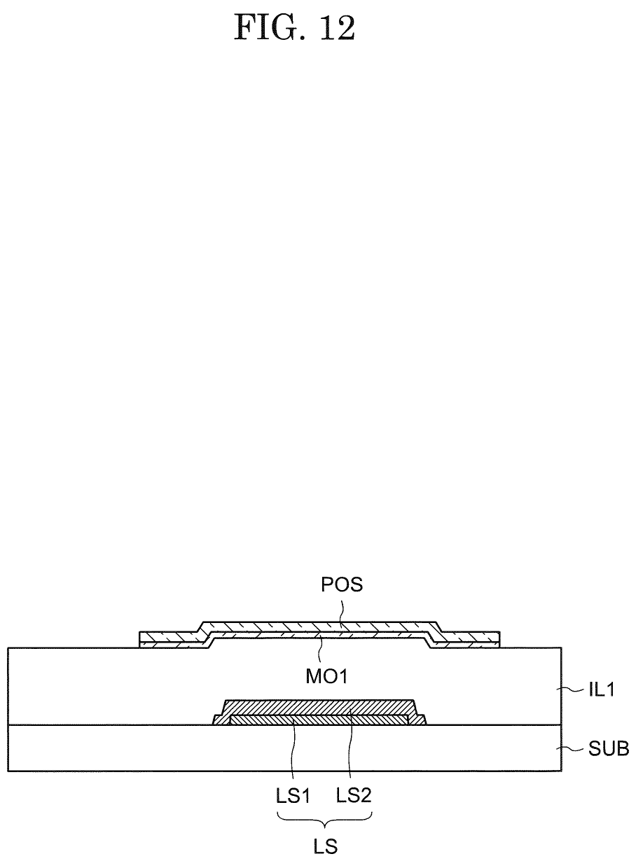

Next, a pattern of the metal oxide layer MO1 is formed using the oxide semiconductor layer POS as a mask (see “MO1 pattern formation” in step S1007 shown in FIG. 7 and see FIG. 12). The metal oxide layer MO1 is etched using the crystallized oxide semiconductor layer POS as a mask. Wet etching may be used, or dry etching may be used as the etching of the metal oxide layer MO1. For example, dilute hydrofluoric acid (DHF) is used as the wet etching. The crystallized oxide semiconductor layer POS has etching resistance to dilute hydrofluoric acid as compared with the amorphous oxide semiconductor layer AOS. Therefore, the metal oxide layer MO1 can be etched using the oxide semiconductor layer POS as a mask. As a result, a photolithography process can be omitted.

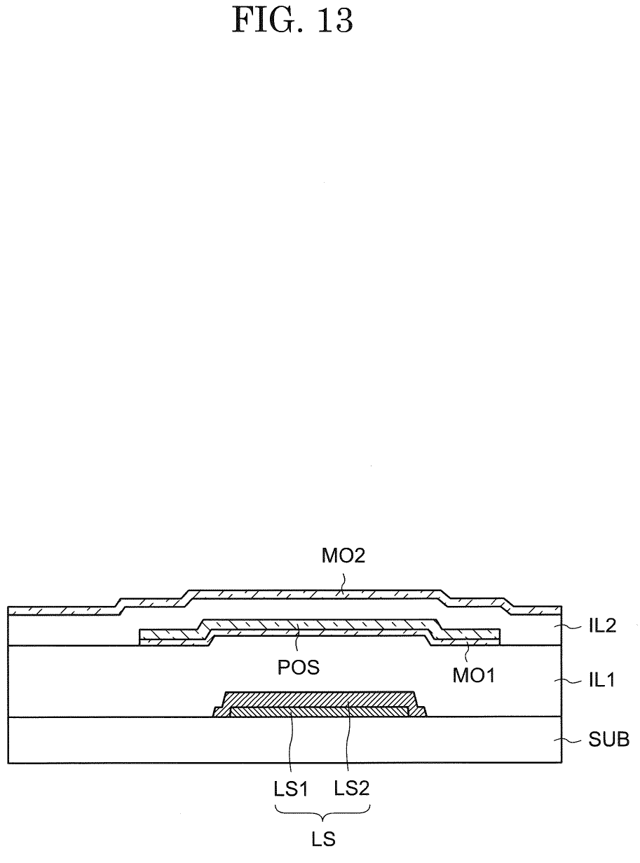

Next, the second insulating layer IL2 is formed on the oxide semiconductor layer POS (see “IL2 deposition” in step S1008 shown in FIG. 7 and see FIG. 13).

Refer to the description of the first insulating layer IL1 for the deposition method and insulating material of the second insulating layer IL2. In addition, for example, a thickness of the second insulating layer IL2 is 50 nm or more and 150 nm or less.

An insulating material containing oxygen is preferably used as the second insulating layer IL2. In addition, an insulating layer with few defects is preferably used as the second insulating layer IL2. For example, in the case where a composition ratio of oxygen in the second insulating layer IL2 is compared with a composition ratio of oxygen in an insulating layer having the same composition as in the second insulating layer IL2 (hereinafter referred to as “other insulating layer”), the composition ratio of oxygen in the second insulating layer IL2 is closer to the stoichiometric ratio with respect to the insulating layer than the composition ratio of oxygen in the other insulating layer. For example, in the case where silicon oxide (SiOₓ) is used for each of the second insulating layer IL2 and the third insulating layer IL3, the composition ratio of oxygen in the silicon oxide used as the second insulating layer IL2 is closer to the stoichiometric ratio of silicon oxide than the composition ratio of oxygen in the silicon oxide used as the third insulating layer IL3. For example, a layer in which no defects are observed when evaluated by an electron-spin resonance method (ESR) may be used as the second insulating layer IL2.

In order to form an insulating layer with few defects as the second insulating layer IL2, the second insulating layer IL2 may be deposited at a deposition temperature of 350° C. or higher. In addition, a process of implanting oxygen may be performed on part of the second insulating layer IL2 after the second insulating layer IL2 is formed. In the present embodiment, silicon oxide is formed at a deposition temperature of 350° C. or higher in order to form an insulating layer with few defects as the second insulating layer IL2.

Next, a metal oxide layer MO2 containing aluminum as a main component is formed on the second insulating layer IL2 (see “MO2 deposition” in step S1009 shown in FIG. 7 and see FIG. 13).

Refer to the description of the metal oxide layer MO1 for the deposition method and insulating material of the metal oxide layer MO2. Oxygen is implanted into the second insulating layer IL2 by the deposition of the metal oxide layer MO2. For example, a thickness of the metal oxide layer MO2 is 2 nm or more and 100 nm or less, 2 nm or more and 50 nm or less, 2 nm or more and 30 nm or less, or 2 nm or more and 15 nm or less. In the present embodiment, aluminum oxide is used as the metal oxide layer MO2. Aluminum oxide has a high barrier property against gas. In the present embodiment, the aluminum oxide used as the metal oxide layer MO2 suppresses the oxygen implanted into the second insulating layer IL2 from diffusing outward during the deposition of the metal oxide layer MO2.

For example, in the case where the metal oxide layer MO2 is formed by a sputtering method, a process gas used in the sputtering remains in the film of the metal oxide layer MO2. For example, in the case where Ar is used as the process gas for sputtering, Ar may remain in the film of the metal oxide layer MO2. The remaining Ar can be detected by a SIMS (Secondary Ion Mass Spectrometry) analysis on the metal oxide layer MO2.

A heat treatment (oxidation annealing treatment) for supplying oxygen to the oxide semiconductor layer POS is performed in a state where the second insulating layer IL2 is formed on the oxide semiconductor layer POS and the metal oxide layer MO2 is formed on the second insulating layer IL2 (see “oxidation annealing treatment” in step S1010 shown in FIG. 7 and see FIG. 13).

Many oxygen defects occur on the upper surface and the side surface of the oxide semiconductor layer POS during the process from the deposition of the oxide semiconductor layer POS to the deposition of the second insulating layer IL2 on the oxide semiconductor layer POS. Oxygen released from the first insulating layer IL1 is supplied to the upper surface and the side surface of the oxide semiconductor layer POS by the oxidation annealing treatment, and the oxygen defects are repaired.

In the above-described oxidation annealing treatment, the oxygen implanted in the second insulating layer IL2 is blocked by the metal oxide layer MO2, so that the oxygen is suppressed from being released into the atmosphere. Therefore, the oxygen is efficiently supplied to the oxide semiconductor layer POS by the oxidation annealing treatment, and the oxygen defects are repaired.

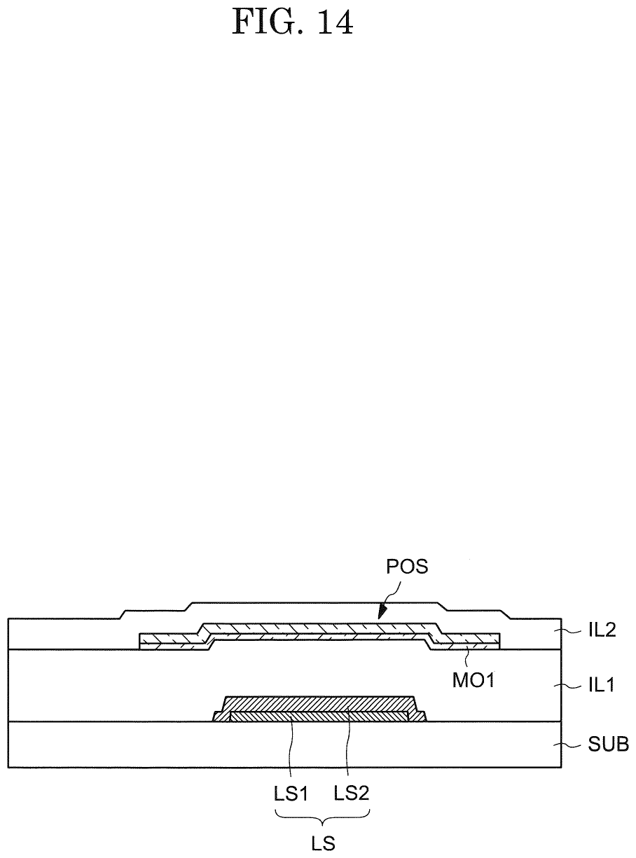

Next, after the oxidation annealing treatment, the metal oxide layer MO2 is etched (removed) (see “MO2 removal” in step S1011 shown in FIG. 7 and see FIG. 14). Wet etching may be used, or dry etching may be used as the etching of the metal oxide layer MO2. For example, dilute hydrofluoric acid (DHF) is used as the wet etching. The metal oxide layer MO2 formed on the entire surface is removed by the etching. In other words, the metal oxide layer MO2 is removed without using a mask. In other words, the etching removes all the metal oxide layer MO2 in a region overlapping the oxide semiconductor layer POS formed in one pattern at least in a plan view.

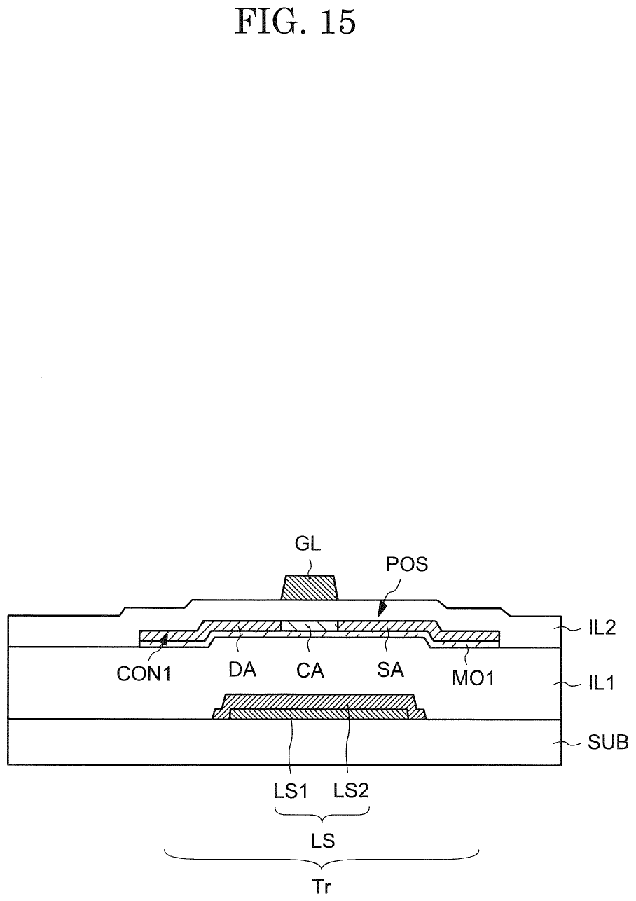

Next, the gate wiring GL is formed on the second insulating layer IL2 (see “GL formation” in step S1012 shown in FIG. 7 and see FIG. 15). Refer to the description of the light-shielding layer LS for the deposition method and insulating material of the gate wiring GL. The gate wiring GL is arranged along the first direction D1.

Next, impurities are added to the oxide semiconductor layer POS using the gate wiring GL as a mask (see “SA, DA formation” in step S1013 shown in FIG. 7 and see FIG. 15). Although the case where the impurity is added by ion implantation is described in the present embodiment, an ion doping method may be used.

Specifically, an impurity element is added to the oxide semiconductor layer POS through the second insulating layer IL2 by ion implantation, so that the source region SA and the drain region DA are formed. For example, argon (Ar), phosphorus (P), or boron (B) may be used as the impurity element. In addition, in the case where boron (B) is added by the ion implantation method, the acceleration energy may be set to 20 keV or more and 40 keV or less, and the implantation amount of boron (B) may be set to 1×10¹⁴ cm⁻² or more and 1×10¹⁶ cm⁻² or less.

The concentration of the impurity element contained in the source region SA and the drain region DA is preferably 1×10¹⁸ cm⁻³ or more and 1×10²¹ cm⁻³ or less as measured by a SIMS (Secondary Ion Mass Spectrometry) analysis. In addition, in the case where the source region SA and the drain region DA contain the impurity element at a concentration of 1×10¹⁸ cm⁻³ or more and 1×10²¹ cm⁻³ or less, it is presumed that the impurity element was intentionally added by the ion implantation method or the doping method.

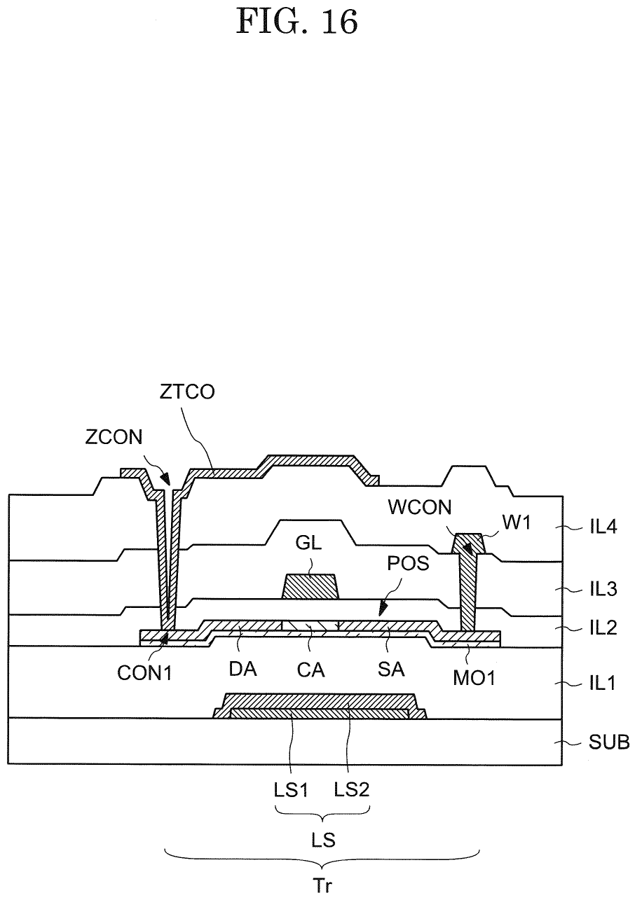

Next, the third insulating layer IL3 is deposited on the second insulating layer IL2 and the gate wiring GL (see “IL3 deposition” in step S1014 shown in FIG. 7 and see FIG. 16). Refer to the description of the first insulating layer IL1 for the deposition method and insulating material of the third insulating layer IL3.

Next, the contact hole WCON reaching the source region SA is formed in the third insulating layer IL3. After that, the wiring W1 is formed on the third insulating layer IL3, and the wiring W1 is connected to the source region SA via the contact hole ZCON (see “W1 formation” in step 1015 shown in FIG. 7 and see FIG. 16). Refer to the description of the light-shielding layer LS for the deposition method and insulating material of the wiring W1. The wiring W1 is arranged along the second direction D2.

Next, the fourth insulating layer IL4 is formed on the third insulating layer IL3 and the wiring W1 (see “IL4 deposition” in step S1016 shown in FIG. 8 and see FIG. 16). Refer to the description of the first insulating layer IL1 for the deposition method and insulating material of the fourth insulating layer IL4.

Next, the contact hole ZCON reaching the drain region DA is formed in the fourth insulating layer IL4. After that, the connecting electrode ZTCO is formed on the fourth insulating layer IL4 to connect the connecting electrode ZTCO to the drain region DA via the contact hole ZCON (see “ZTCO formation” in step S1017 shown in FIG. 8 and see FIG. 16).

The connecting electrode ZTCO is formed by processing an oxide conductive layer (also referred to as a transparent conductive layer) having light transmittance formed by a sputtering method. A transparent conductive material such as a mixture of indium oxide and tin oxide (ITO) or a mixture of indium oxide and zinc oxide (IZO) can be used as the oxide conductive layer. A transparent conductive material other than the above may be used as the oxide conductive layer.

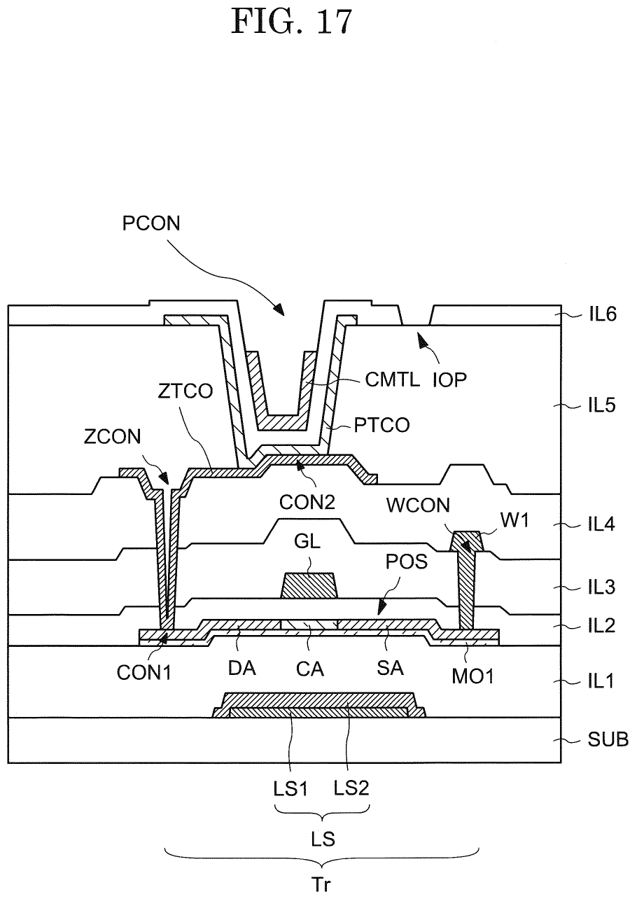

Next, the fifth insulating layer IL5 is formed on the fourth insulating layer IL4 and the connecting electrode ZTCO (see “IL5 deposition” in step S1018 shown in FIG. 8 and see FIG. 17).

The fifth insulating layer IL5 is formed by applying an organic insulating material and baking. An organic resin such as a polyimide resin, an acryl resin, an epoxy resin, a silicone resin, a fluororesin, or a siloxane resin is used as the organic insulating material. After that, part of the fifth insulating layer is exposed and removed to form the contact hole PCON exposing the connecting electrode ZTCO.

Next, the pixel electrode PTCO is formed on the fifth insulating layer IL5, and the pixel electrode PTCO is connected to the connecting electrode ZTCO via the contact hole PCON (see “PTCO formation” in step S1019 shown in FIG. 8 and see FIG. 17). Refer to the description of the connecting electrode ZTCO for the deposition method and transparent conductive material of the pixel electrode PTCO.

Next, the sixth insulating layer IL6 is formed on the pixel electrode PTCO (see “IL6 deposition” in step S1020 shown in FIG. 8 and see FIG. 17).

Refer to the description of the first insulating layer IL1 for the deposition method and insulating material of the sixth insulating layer IL6. The sixth insulating layer IL6 functions as a dielectric for forming a capacitance. In addition, the sixth insulating layer IL6 functions as the first inorganic layer. A thickness of the sixth insulating layer IL6 is at least 30 nm or more and 50 nm or more and 200 nm or less. In the present embodiment, silicon nitride is formed as the sixth insulating layer IL6.

Next, the opening IOP is formed in the sixth insulating layer IL6 (see “IOP formation” in step S1021 shown in FIG. 8 and see FIG. 17). As described above, the opening IOP is arranged to release moisture contained in the fifth insulating layer IL5.

The area of the opening IOP is preferably less than 15% of the area of the pixel. In other words, the sixth insulating layer IL6 covers the fifth insulating layer IL5 at a coverage of 85% or more, preferably 90% or more, and more preferably 95% or more with respect to the area of the pixel. The opening IOP is not limited to one per pixel and may be plural. In addition, in the case where a plurality of openings IOP is arranged per pixel, the total area of the plurality of openings IOP may be less than 15% of the area of the pixel. The opening IOP is preferably arranged in a region overlapping the oxide semiconductor layer POS. Furthermore, the opening IOP is more preferably arranged in a region of the oxide semiconductor layer POS (that is, the channel region CA) where the gate wiring overlaps. Arranging the opening IOP overlapping the oxide semiconductor layer POS or the channel region CA of the oxide semiconductor layer POS makes it possible to release the moisture contained in the organic resin layer by an annealing treatment to be described later and suppress the moisture contained in the organic resin layer from entering the oxide semiconductor layer POS. However, the position at which the opening IOP is arranged is not limited to the above-described position, and may be arranged, for example, at a position overlapping the wiring W1 or at a position not overlapping the oxide semiconductor layer POS.

Next, an annealing treatment is performed in a state where the sixth insulating layer IL6 covers the fifth insulating layer IL5 (see “annealing treatment” in step S1022 shown in FIG. 8 and see FIG. 17). For example, the temperature of the annealing treatment is 150° C. or higher and 300° C. or lower. Performing the annealing treatment makes it possible to release the moisture contained in the fifth insulating layer IL5.

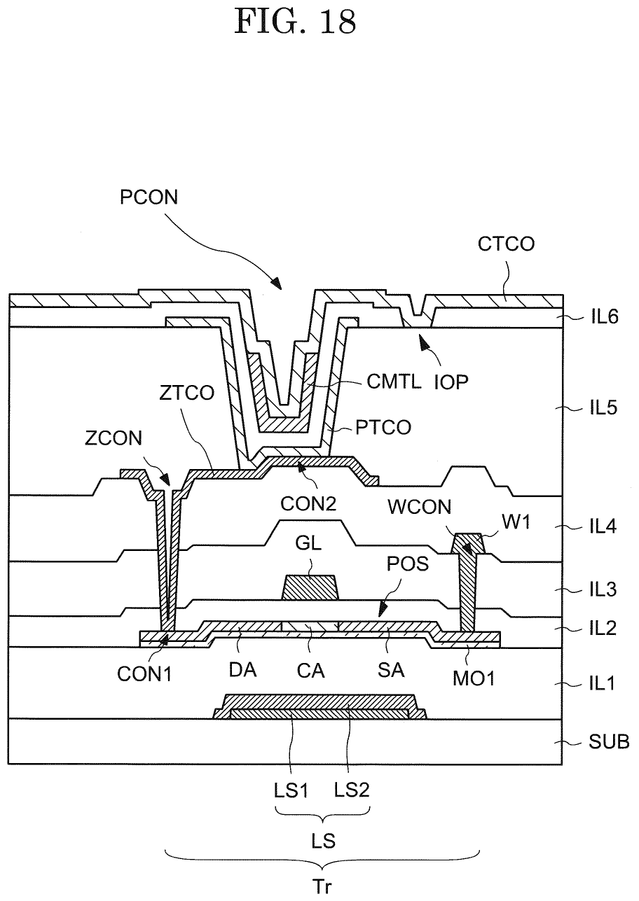

Next, the common auxiliary electrode CMTL is formed on the sixth insulating layer IL6 (see “CMTL formation” in step S1023 shown in FIG. 8 and see FIG. 18).

Refer to the description of the light-shielding layer LS for the deposition method and conductive material of the common auxiliary electrode CMTL. The common auxiliary electrode CMTL is formed in a grid pattern so as to overlap the gate wiring GL and the wiring W1.

Next, the common electrode CTCO is formed on the sixth insulating layer IL6 and the common auxiliary electrode CMTL (see “CTCO formation” in step S1024 shown in FIG. 8 and see FIG. 18). Refer to the description of the connecting electrode ZTCO for the deposition method and transparent conductive material of the common electrode CTCO. The common electrode CTCO functions as the second inorganic layer. A thickness of the common electrode CTCO may be at least 30 nm or more, and 50 nm or more and 200 nm or less. The common electrode CTCO is in contact with the fifth insulating layer IL5 in the opening IOP by forming the common electrode CTCO. That is, the common electrode CTCO can close the opening IOP arranged in the sixth insulating layer IL6. As a result, it is possible to suppress moisture from being taken into the fifth insulating layer IL5 from the outside via the opening IOP.

Next, the spacer SP is formed on the common electrode CTCO (see “SP formation” in step S1025 shown in FIG. 8). The spacer SP is formed in the contact hole PCON. Finally, the array substrate manufactured as described above and the counter substrate on which the color filters and the spacer are formed may be bonded to each other via a sealing material and a liquid crystal layer.

The display device 10 according to an embodiment of the present invention can be manufactured through the above process.

Typically, in an FFS type liquid crystal display device, a pixel electrode, a capacitance insulating layer, and a common electrode are arranged on the organic resin layer, or a common electrode, a capacitance insulating layer, and a pixel electrode are stacked on the organic resin layer. In the case where the pixel electrode is arranged on the organic resin layer, the pixel electrode is often arranged so as not to overlap the source wiring or the like in order to suppress capacitive coupling between the pixel electrode and the wiring. In addition, a slit pattern may be arranged in the pixel electrode. Therefore, the pixel electrode covers the pixel at a coverage of less than 85% of the area of the pixel. In addition, in the case where the common electrode is arranged on the organic resin layer, a slit pattern may be arranged on the common electrode, or an opening may be arranged above the transistor. Therefore, the common electrode covers the pixel at a coverage of less than 85% of the area of the pixel. Therefore, moisture can be released from the organic resin layer even if the annealing treatment is performed in a state where the pixel electrode or the common electrode is arranged on the organic resin layer, but the moisture is taken in again in the subsequent process. When the moisture contained in the organic resin layer enters the oxide semiconductor layer, the properties of the transistor fluctuate.

In addition, a capacitance insulating layer is arranged on the organic resin layer or the common electrode so as to cover the active region on the pixel electrode in the FFS type liquid crystal display device. Even if the annealing treatment is performed in a state where the capacitance insulating layer is formed on the entire surface, the moisture contained in the organic resin layer is blocked by the insulating layer and the pixel electrode, so that the moisture cannot be released from the organic resin layer. Therefore, excess moisture remains in the organic resin layer, so that the moisture enters the oxide semiconductor layer, and the properties of the transistor fluctuate.

In the method of manufacturing the display device according to an embodiment of the present invention, moisture contained in the fifth insulating layer IL5 made of an organic resin is sufficiently released from the opening IOP formed in the first inorganic layer by the annealing treatment, and then the opening IOP is closed by the second inorganic layer. As a result, it is possible to maintain a condition in which the quantity of moisture contained in the organic resin layer is reduced. Therefore, it is possible to suppress moisture contained in the organic resin layer from entering the oxide semiconductor layer. As a result, it is possible to suppress fluctuation in the properties of the transistor, and it is possible to improve the reliability of the display device.

### [7. Crystal Structure of Oxide Semiconductor Layer]

The oxide semiconductor layer POS described in the present embodiment contains the Poly-OS. A particle diameter of the crystal grain contained in the Poly-OS observed from the upper surface of the oxide semiconductor layer POS (or a thickness direction of the oxide semiconductor layer POS) is 0.1 μm or more, preferably 0.3 μm or more, and more preferably 0.5 μm or more. For example, the particle diameter of the crystal grain can be obtained using a cross-sectional SEM observation, a cross-sectional TEM observation, or an electron back scattered diffraction (EBSD) method.

In the Poly-OS, the plurality of crystal grains may have one type of crystal structure, or may have a plurality of types of crystal structures. The crystal structure of the Poly-OS can be identified using an electron diffraction method or an XRD method, and the like. That is, the crystal structure of the oxide semiconductor layer POS can be identified by the electron diffraction method, the XRD method, or the like.

The crystal structure of the oxide semiconductor layer POS is preferably a cubic crystal structure. A cubic crystal has a high symmetric crystal structure, and even if an oxygen defect is generated in the oxide semiconductor layer POS, structural relaxation hardly occurs, and the crystal structure is stable. As described above, increasing the ratio of the indium element makes it possible to control the crystal structure of each of the plurality of crystal grains, and the oxide semiconductor layer POS having a cubic crystal structure can be formed.

In the transistor containing the oxide semiconductor layer POS manufactured by the above-described manufacturing method, it is possible to obtain electrical characteristics having a mobility of 50 cm²/Vs or more, 55 cm²/Vs or more, or 60 cm²/Vs or more in a region where a channel length L of the channel region CA is 2 μm or more and 4 μm or less and a channel width of the channel region CA is 2 μm or more and 25 μm or less. The mobility in the present embodiment is the field-effect mobility in a saturated region of the transistor, and means the largest value of the field-effect mobility in a region where a potential difference (Vd) between the source electrode and the drain electrode is larger than a voltage (Vg−Vth) obtained by subtracting a threshold voltage (Vth) from a voltage (Vg) supplied to the gate electrode.

In the process of forming the transistor Tr, the formation of the metal oxide layer MO1 arranged below the oxide semiconductor layer POS may be omitted. In this case, the process of step S1003 and step S1007 shown in FIG. 7 may be omitted. Furthermore, in the process of forming the transistor Tr, the step of forming the metal oxide layer MO2 on the second insulating layer IL2 and then performing the annealing treatment may be omitted. In this case, the process of step S1009 and step S1011 shown in FIG. 7 may be omitted. Even when the formation of the metal oxide layer MO1 or the formation of the metal oxide layer MO2 is omitted, a good Poly-OS can be formed.

In the process of forming the transistor, the Poly-OS can be formed even if the above-described step is omitted. The electrical characteristics having the mobility of 30 cm²/Vs or more, 35 cm²/Vs or more, or 40 cm²/Vs or more can be obtained in a range where the channel length L of the channel region CA in the transistor using the Poly-OS as the oxide semiconductor layer POS is 2 μm or more and 4 μm or less, and the channel width of the channel region CA is 2 μm or more and 25 μm or less.

In addition, IGZO may be used instead of the oxide semiconductor layer POS. Even when IGZO is used as the oxide semiconductor material, it is preferable to release the moisture contained in the organic resin layer from the opening by performing the annealing treatment in a state where the opening is formed in the first inorganic layer arranged on the fifth insulating layer IL5 made of the organic resin. After that, forming the second inorganic layer so as to close the opening makes it possible to suppress moisture from being taken into the organic resin layer from the outside, and it is possible to suppress fluctuations in the properties of the transistor. As a result, the reliability of the display device can be improved.

### [8. First Modification]

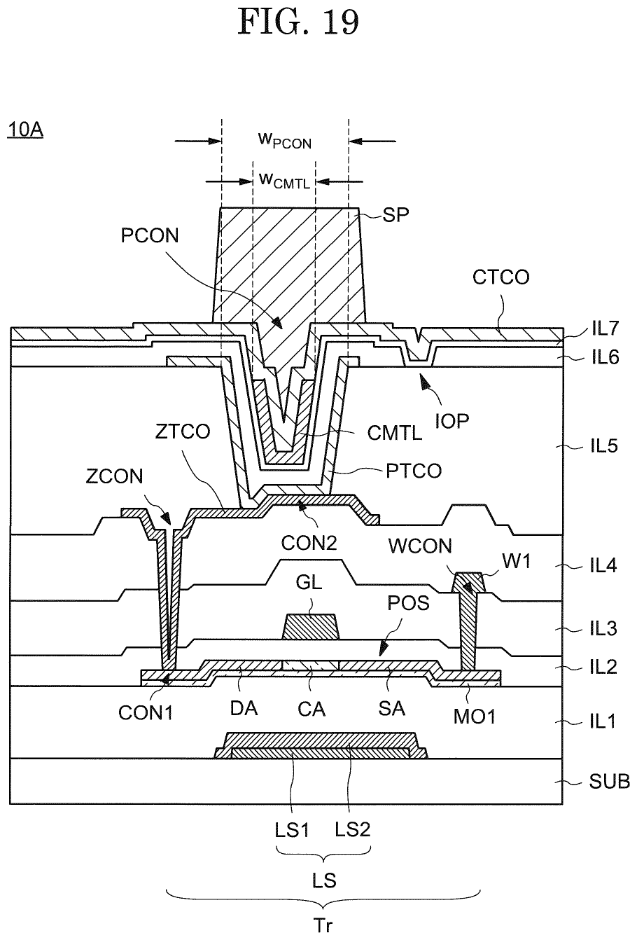

In a first modification, a display device 10A partially different from the display device shown in FIG. 4 will be described with reference to FIG. 19. FIG. 19 shows a configuration in which the opening IOP arranged in the sixth insulating layer IL6 is closed by a seventh insulating layer IL7.

In the display device 10A shown in FIG. 19, the sixth insulating layer IL6 and the seventh insulating layer IL7 are arranged between the pixel electrode PTCO and the common electrode CTCO. The common electrode CTCO has a slit pattern in a region overlapping the pixel electrode PTCO. Refer to the description of the first insulating layer IL1 for the deposition method and insulating material of the seventh insulating layer IL7. Thicknesses of the sixth insulating layer IL6 and the seventh insulating layer IL7 may be appropriately set depending on a size of the capacitance of the storage capacitor 890. The thickness of the seventh insulating layer IL7 may be smaller than the thickness of the sixth insulating layer IL6. The common electrode CTCO is arranged on the seventh insulating layer IL7. When the thickness of each of the seventh insulating layer IL7 and the common electrode CTCO is at least 30 nm or more and 50 nm or more and 200 nm or less, it is possible to suppress moisture from being taken in from the outside. In the first modification, it is sufficient that at least the sixth insulating layer IL6 is included as the first inorganic layer, and it is sufficient that at least the seventh insulating layer IL7 is included as the second inorganic layer.

### [9. Second Modification]

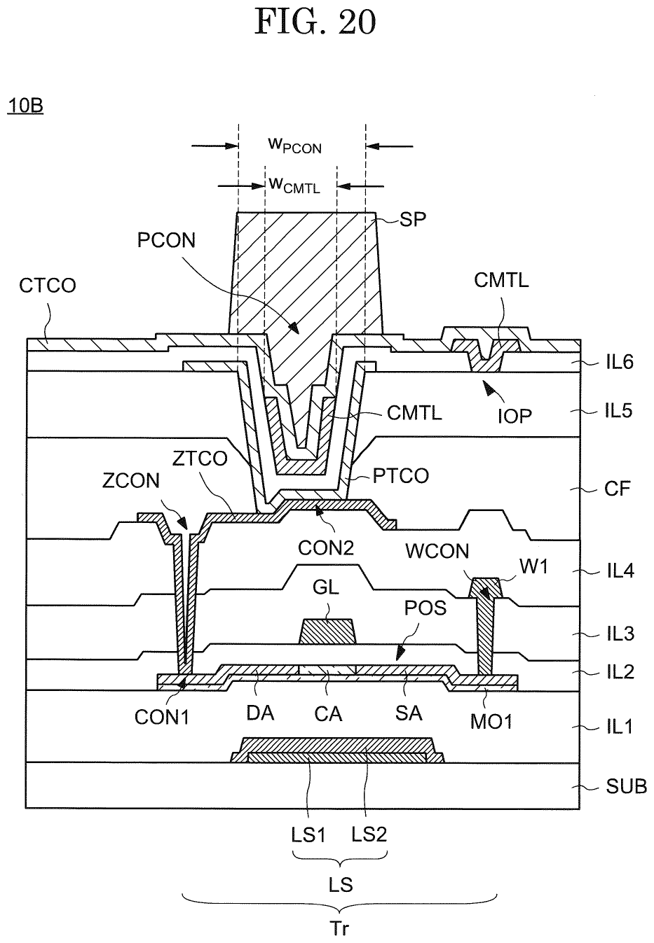

In a second modification, a display device 10B partially different from the display device 10 shown in FIG. 4 will be described with reference to FIG. 20. FIG. 20 shows a configuration in which the opening IOP arranged in the sixth insulating layer IL6 is closed by the common auxiliary electrode CMTL. In addition, a color filter CF is arranged between the fourth insulating layer IL4 and the fifth insulating layer IL5.

In the display device 10B shown in FIG. 20, the opening IOP arranged in the sixth insulating layer IL6 is arranged on the wiring W1. In the present embodiment, the common auxiliary electrode CMTL is arranged above the wiring W1. Therefore, the opening IOP may be closed by the common auxiliary electrode CMTL. In addition, the common electrode CTCO is arranged on the sixth insulating layer IL6 and the common auxiliary electrode CMTL. When the thickness of the common auxiliary electrode CMTL is at least 30 nm or more and 50 nm or more and 200 nm or less, it is possible to suppress moisture from being taken in from the outside. In the second modification, it is sufficient that at least the sixth insulating layer IL6 is included as the first inorganic layer, and it is sufficient that at least the common auxiliary electrode CMTL is included as the second inorganic layer. As a result, it is possible to suppress moisture from being taken in from the opening IOP and the outside.

In the case where the color filter is arranged in the counter substrate in the liquid crystal display device, misalignment may occur when bonding the array substrate and the counter substrate on which the transistor or the like is formed. In a high-definition liquid crystal display device used for VR or the like, the display quality of the display device is degraded due to a slight misalignment between the pixel of the array substrate and the color filter of the counter substrate. Therefore, forming the color filter CF between the fourth insulating layer IL and the fifth insulating layer IL5 makes it possible to suppress the misalignment between the array substrate and the color filter when the array substrate is bonded to the counter substrate. In addition, since the color filter CF is also formed of an organic resin, it contains moisture. After the moisture contained in the color filter CF and the moisture contained in the fifth insulating layer IL5 are released from the opening IOP formed in the sixth insulating layer IL6 by the annealing treatment, the opening IOP is closed by the common auxiliary electrode CMTL, thereby suppressing the moisture from being taken in again from the outside into the opening IOP, the fifth insulating layer IL5, and the color filter CF.

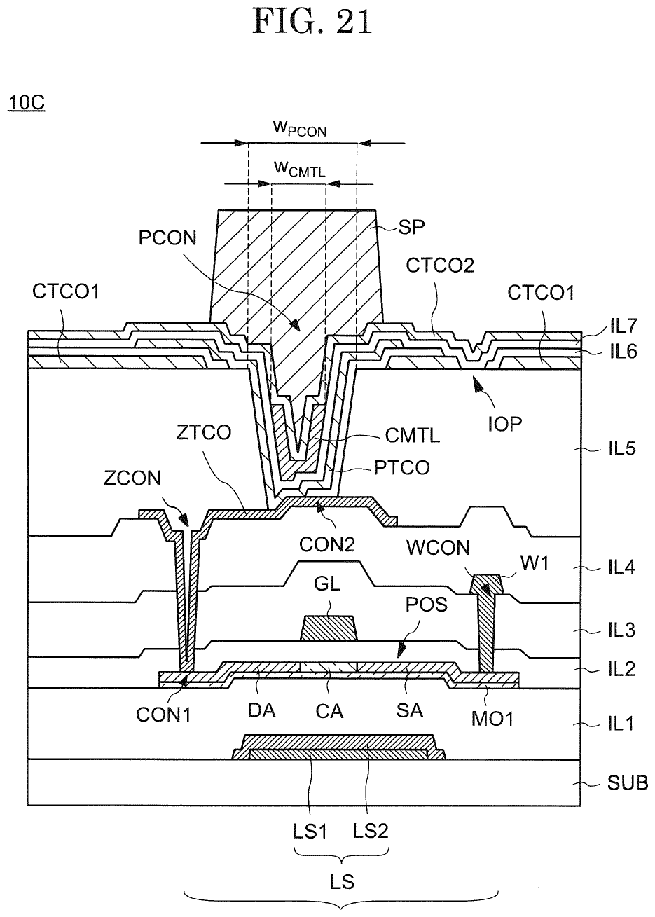

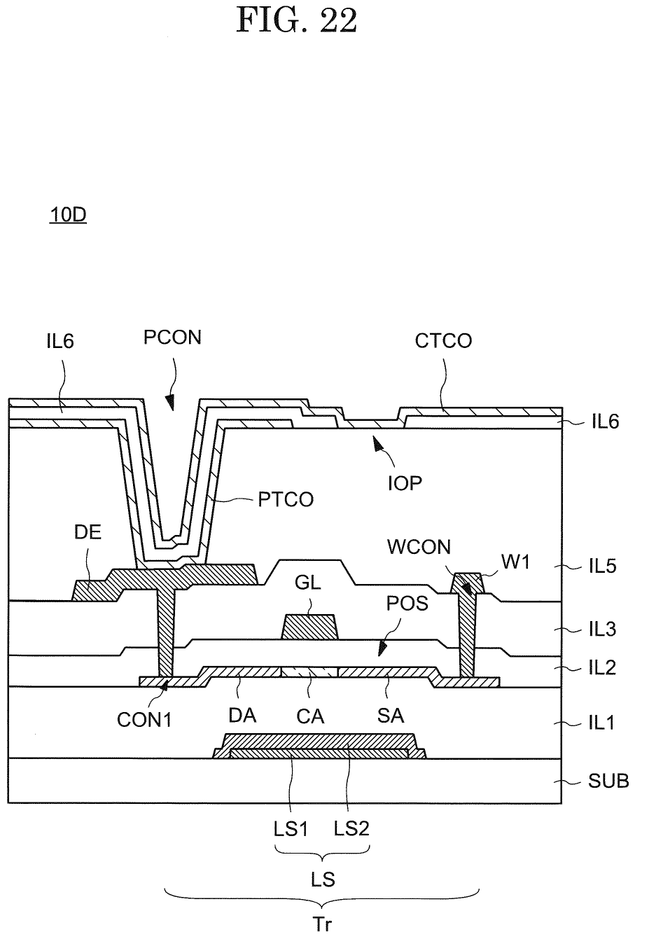

Although not shown, a configuration in which the color filter CF is arranged between the fourth insulating layer IL4 and the fifth insulating layer IL5 may be used in the display device shown in FIG. 4 and FIG. 19 and the display device shown in FIG. 21 and FIG. 22 to be described later.

### [10. Third Modification]

In a third modification, a display device 10C partially different from the display device 10 shown in FIG. 4 will be described with reference to FIG. 21. FIG. 21 shows a configuration in which a capacitance electrode CTCO1 is arranged on the fifth insulating layer IL5.

The capacitance electrode CTCO1 is arranged on the fifth insulating layer IL5 in the display device 10C shown in FIG. 21. A storage capacitor is formed by the capacitance electrode CTCO1, the sixth insulating layer IL6, and the pixel electrode PTCO, and the storage capacitor is formed by the pixel electrode PTCO, the seventh insulating layer IL7, and a common electrode CTCO2. Since the sixth insulating layer IL6 is arranged on the capacitance electrode CTCO1, the capacitance electrode CTCO1 covers the fifth insulating layer IL5 at a coverage of less than 85% of the area of the pixel. An opening may be arranged in the capacitance electrode CTCO1.

The sixth insulating layer IL6 is arranged on the capacitance electrode CTCO1. The sixth insulating layer IL6 preferably covers the fifth insulating layer IL5 at a coverage of 85% or more of the area of the pixel. In addition, the opening IOP may overlap the opening arranged in the capacitance electrode CTCO1. The seventh insulating layer IL7 is arranged on the sixth insulating layer IL6. The seventh insulating layer IL7 is arranged so as to close the opening IOP and the opening arranged in the capacitance electrode CTCO1. Therefore, the seventh insulating layer IL7 is in contact with the fifth insulating layer IL5 at the opening.

In addition, the common electrode CTCO2 is arranged on the seventh insulating layer IL7. Although an example in which the opening arranged in the capacitance electrode CTCO1 overlaps the opening IOP is shown in FIG. 21, the present invention is not limited to this. The opening IOP may be formed in the sixth insulating layer IL6 without forming the opening in the capacitance electrode CTCO1. In the third modification, it is sufficient that at least the sixth insulating layer IL6 is included as the first inorganic layer, and it is sufficient that at least the seventh insulating layer IL7 is included as the second inorganic layer.

Furthermore, for example, a thickness of the seventh insulating layer IL7 may be at least 30 nm or more, 50 nm or more and 200 nm or less. In addition, refer to the description of the connecting electrode ZTCO for the deposition method and transparent conductive material of the capacitance electrode CTCO1 and the common electrode CTCO2. The thickness of the capacitance electrode CTCO1 and the thickness of the common electrode CTCO2 may be at least 30 nm or more, and 50 nm or more and 200 nm or less.

### [11. Fourth Modification]

In a fourth modification, a display device 10D partially different from the display device 10 shown in FIG. 4 will be described with reference to FIG. 22. Although the example in which the wiring W1 and the connecting electrode ZTCO functioning as the drain electrode are arranged on different insulating layers has been described in the display device 10, the wiring W1 and the connecting electrode ZTCO may be arranged on the same insulating layer.

In the display device 10D shown in FIG. 22, the fourth insulating layer IL4 is omitted, and the wiring W1 and the drain electrode DE are arranged on the third insulating layer IL3. The fifth insulating layer IL5 is arranged on the wiring W1 and the drain electrode DE, and the contact hole PCON is formed in the fifth insulating layer IL5. The pixel electrode PTCO is arranged on the fifth insulating layer IL5, and the pixel electrode PTCO is connected to the pixel electrode PTCO and the drain electrode DE via the contact hole PCON. The sixth insulating layer IL6 is arranged on the fifth insulating layer IL5 and the pixel electrode PTCO. The opening IOP is arranged in the sixth insulating layer IL6. The opening IOP is closed by the common electrode CTCO arranged on the sixth insulating layer IL6. In the fourth modification, it is sufficient that at least the sixth insulating layer IL6 is included as the first inorganic layer, and it is sufficient that the common electrode CTCO is included as the second inorganic layer.

Each of the embodiments described above as an embodiment of the present invention can be appropriately combined and implemented as long as no contradiction is caused. Furthermore, the addition, deletion, or design change of components, or the addition, deletion, or condition change of processes as appropriate by those skilled in the art based on each embodiment are also included in the scope of the present invention as long as they are provided with the gist of the present invention.

Furthermore, it is understood that, even if the effect is different from those provided by each of the above-described embodiments, the effect obvious from the description in the specification or easily predicted by persons ordinarily skilled in the art is apparently derived from the present invention.

What is claimed is:

1. A display device having a plurality of pixels arranged in a matrix along a first direction and a second direction intersecting the first direction, each of the plurality of pixels comprising:
a transistor including an oxide semiconductor layer, a gate wiring extending in the first direction opposite the oxide semiconductor layer, and a gate insulating layer between the oxide semiconductor layer and the gate wiring;
a first conductive layer provided on at least one first insulating layer above the transistor and in contact with the oxide semiconductor layer;
a second insulating layer provided on the first conductive layer;
a first inorganic layer provided on the second insulating layer and having openings therein; and
a second inorganic layer provided on the first inorganic layer and in contact with the second insulating layer in the opening,
wherein a coverage of the first inorganic layer covering the first insulating layer is 85% or more of an area of the pixel.

2. The display device according to claim 1, wherein
the first inorganic layer has a second transparent conductive layer and a first inorganic insulating layer on the second transparent conductive layer,
the second transparent conductive layer is connected to the first conductive layer, and
the opening is provided in the first inorganic insulating layer.

3. The display device according to claim 2, wherein
the second inorganic layer includes a third transparent conductive layer, and
the third transparent conductive layer is in contact with the second insulating layer in the opening and has a slit pattern in a region overlapping the second transparent conductive layer.

4. The display device according to claim 2, wherein
the second inorganic layer includes a second inorganic insulating layer, and
the second inorganic layer is in contact with the second insulating layer at the opening.

5. The display device according to claim 4, wherein
the second inorganic layer includes a fourth transparent conductive layer provided on the second inorganic insulating layer, and
the fourth transparent conductive layer has a slit pattern in a region overlapping the second transparent conductive layer.

6. The display device according to claim 2, wherein
the second inorganic layer includes a metal layer, and
the metal layer is in contact with the second insulating layer at the opening.

7. The display device according to claim 1, wherein
the first inorganic layer includes a first inorganic insulating layer and a second transparent conductive layer provided on the first inorganic insulating layer,
the second transparent conductive layer is connected to the first conductive layer via a contact hole in the first inorganic insulating layer, and
the opening is arranged in the first inorganic insulating layer.

8. The display device according to claim 7, wherein
the second inorganic layer includes a second inorganic insulating layer, and
the second inorganic insulating layer is contact with the second insulating layer at the opening.

9. The display device according to claim 1, further comprising:
a first wiring provided between the transistor and the first conductive layer and in contact with the oxide semiconductor layer,
wherein
the first conductive layer is translucent.

10. The display device according to claim 1, further comprising:
a first wiring provided on the first insulating layer and in contact with the oxide semiconductor layer,
wherein
the first wiring is provided along the second direction.

11. The display device according to claim 1, wherein
the opening is provided in a region overlapping the oxide semiconductor layer.

12. The display device according to claim 1, wherein
the opening is located in the oxide semiconductor layer in a region overlapping a region where the gate wiring overlaps in the oxide semiconductor layer.

13. The display device according to claim 1, wherein
the oxide semiconductor layer has a polycrystalline structure.

14. The display device according to claim 1, further comprising:
an aluminum oxide layer between the gate insulating layer and the oxide semiconductor layer.
